(19) United States
(12) Patent Application Publication
(10) Pub. No.: US 2010/0132771 A1
(43) Pub. Date: Jun. 3, 2010

(54) 3D Carbon Nanotubes Membrane as a Solar Energy Absorbing Layer

(75) Inventor: Jennifer LU, Merced, CA (US)

Correspondence Address: FOLEY & LARDNER LLP, 975 PAGE MILL ROAD, PALO ALTO, CA, 94304, US

(73) Assignee: The Regents of the University of California

(21) Appl. No.: 12/573,036

(22) Filed: Oct. 2, 2009

Related U.S. Application Data
(60) Provisional application No. 61/103,148, filed on Oct. 6, 2008.

(51) Int. Cl. H01L 31/0352; H01L 31/00; H01L 31/18

(52) U.S. Cl. 136/252; 257/21; 438/73; 257/E31.033; 257/E21.158

(57) ABSTRACT

This invention relates to the field of optoelectronics, and more particularly, to the use of high quality, low defect suspended single-walled carbon nanotubes for optoelectronic devices.

### CROSS-REFERENCE TO RELATED APPLICATIONS

This application claims the benefit under 35 U.S.C. §119(e) of U.S. Provisional Application No. 61/103,148, filed Oct. 6, 2008, the contents of which are hereby incorporated by reference into the present disclosure.

### FIELD OF THE INVENTION

This invention relates to the field of optoelectronics, and more particularly, to the use of nanorods for the fabrication of optoelectronic devices.

### BACKGROUND OF THE INVENTION

Throughout this disclosure, various technical and patent publications are referenced to more fully describe the state of the art to which this invention pertains. These publications are incorporated by reference, in their entirety, into this application.

Given the immense energy demand of the world today, alternative sources of cheap, abundant, clean energy is required. Solar cells, which harness the power of the sun, can replace fossil fuels and provide abundant clean energy. The solar cell, in order to be effective, must have a long lifetime and be highly efficient. New highly efficient and cost effective materials developed by advances in the field of nanotechnology offer a new generation of optoelectronic devices for use in solar cells.

Optoelectronic devices are electronic devices that interact with light, including visible and invisible forms of radiation such as gamma rays, X-rays, ultraviolet and infrared. Optoelectronic devices are electrical-to-optical or optical-to-electrical transducers, or instruments that use such devices in their operation, such as photovoltaic cells and photodetectors.

Nanotubes are typically, but not exclusively, carbon molecules and have novel properties that make them potentially useful in a wide variety of applications in electronics, optics, optoelectronics, biological sensing and drug delivery. They exhibit extraordinary strength and excellent electrical properties. The name is derived from their size, since the diameter of a nanotube can be on the order of a few nanometers (approximately 50,000 times smaller than the width of a human hair), while they can be up to several centimeters in length. There are two main types of nanotubes: single-walled carbon nanotubes (SWCNTs) and multi-walled carbon nanotubes (MWCNTs). Bulk synthesized nanotubes naturally group into “ropes” due to strong Van der Waals forces.

Carbon nanotubes (CNTs) are generally produced by three main techniques, arc discharge (Iijima et al. Nature, 1991, 354, 56-58 and Ebbesen et al. Nature 1992, 358, 220-222), laser ablation (Anazawa et al. U.S. Pat. No. 7,132,039, Guo et al. Chemical Physics Letters, 1995, 243, 49-54, A. Thess et al. Science 1996, 273, 483-487) and chemical vapor deposition (Lee, et al. U.S. Pat. No. 6,350,488; Hirakata et al. U.S. Pat. No. 6,936,228, Resasco, et al. U.S. Pat. No. 6,333,016, Awasthi et al. J. Nanosci. Nanotechnol. 2005, 5(10), 1616-36). The arc discharge method involves a carbon vapor as a precursor to CNTs that is created by an arc discharge between two carbon electrodes. The carbon nanotubes can be synthesized from the resulting carbon vapor. Laser ablation technique involves a high-power laser beam coming in contact with a volume of carbon-rich gas (methane or carbon monoxide, for example). Laser ablation produces a small amount of clean nanotubes, whereas arc discharge generally produces large quantities of impure CNTs. Chemical vapor deposition (CVD) often utilizes a catalyst nanoparticle and two gases which are bled into the reactor: a process gas (such as ammonia, nitrogen, hydrogen, etc.) and a carbon-containing gas (such as acetylene, ethylene, ethanol, methane, etc.). Nanotubes grow at the sites of catalyst nanoparticle as the carbon-containing gas is broken apart. It is generally believed that oversaturated carbon is diffused to the edges of the catalyst particle wherein this leads to the growth of CNTs. The catalyst particles either stay at the tips of the growing nanotube during the growth process, or remain at the nanotube base, depending on the adhesion between the catalyst particle and the substrate on which the catalyst particle is disposed. Therefore, in order to control the diameter and location of the CNTs in general, one must use uniformly sized catalyst particles at predefined locations.

Single-walled nanotubes are key to the formation electronic devices from carbon nanotubes as they exhibit important electric properties that are not shared by the multi-walled carbon nanotube (MWNT) variant. Semiconducting single-walled carbon nanotubes, exhibiting ballistic electron transport properties and exceptionally high current carrying capability, are direct bandgap materials (Javey, et al. Nature, 2003, 424, 654-657, Moon, et al. Nanotechnology, 2007, 18, 235201, Dresselhaus, et al. “Carbon Nanotubes”, Springer, Berlin, 2001, Itkis, et al. Science, 2006, 312(5772), 413-416, Connell, et al. Science, 2002, 297, 593-596). Additionally, the spectral absorption range spans from the visible to the infrared (Javey, et al., supra, Dresselhaus, et al., supra, Hagen, et al. Nano Letters, 2003, 3, 383-388, Misewich, et al. Science, 2003, 300, 783-786). A recent study has indicated that the absorption coefficient of CNTs is extremely high, at least one order of magnitude greater than that of mercury cadmium telluride, the most popular photoconductor for 2D arrays of IR photodetectors (Saito, et al. “Physical Properties of Carbon Nanotubes”, Imperial College, London, 1998). This has led to widespread investigation of the use of CNTs for optoelectronic applications (Saito, et al., supra, Freitag, et al. Nano Letters, 2003, 3, 1067-1071, Lee J. U. Applied Physics Letters, 2005, 87, 073101, Wei, et al. Nano Letters, 2007, 7, 2317-2321, Chen, et al. Science, 2005, 310(5751), 1171-1174).

CNTs intrinsically are excellent solar absorber and photon detection materials. Compared to other photosensitive materials, CNTs have extremely large surface area owing to their small diameter so that they can be very sensitive. CNTs possess excellent mechanical properties, superb thermal and chemical stabilities due to sp² hybridization. CNTs as photoabsorbing materials offer unique advantage over quantum dots and wires. The CNT surface is seamlessly perfect with no dangling bonds present thus are much more stable. Unlike most organic materials, CNTs are neither easily oxidized nor thermally degraded.

Reduction in dimensionality alters electronic structure. CNT properties drastically change with tube geometry: chirality and diameter. It has been confirmed that the bandgap and related optical transition energies in CNTs are inversely proportional to tube diameter. Unlike traditional ways of changing composition and structure, tuning tube diameter can lead to predictable variation in absorption spectra. If a system contains a large number of CNTs, arranged in a 3D configuration, with small diameter tubes near the surface and large diameter tubes close to the bottom, a vertically graded structure which will absorb a large portion of the solar spectra can be created.

Most recent optical studies indicate that because of dimensional confinement, the majority of photoexcitations are in the form of excitons, which are correlated electron-hole pairs, rather than free carriers (Song, et al. Optics Letters, 2007, 32(11), 1399-1401, Spataru, et al. Physical Review Letters, 2005, 95, 247402, Wang, et al. Physical Review Letters, 2004, 92(17), 177401, Jones, et al. Physical Review B, 2005, 71(11), 115426, Kono, et al. Applied Physical Letters, 1994, 64, 1564-1566, Lomascolo, et al. Applied Physical Letters, 1999, 74, 676-678). Binding energies of these excitons are very large, often as high as 0.5 eV, so exciton effects can be observed at room temperature (Lomascolo, et al., supra, Catalin, et al. Physical Review Letters, 2004, 92, 077402, Perebeinos, et al. Physical Review Letters, 2004, 92, 257402). As a result, the CNT optical properties are sensitive to these excitonic effects.

Predictions for the excitonic recombination times in single-walled CNTs are on the order of 10 ns and can be as high as 100 ns (Shen, et al. Physcal Review B, 2005, 71, 125427, Wang, et al. Science, 2005, 308(5723), 838-841, Araujo, et al. Physical Review Letters, 2007, 98, 67401). It is at least comparable to, or perhaps exceeds the exciton radiative lifetime of GaAs and InGaAs nanowires (Korovyanko, et al. Physical Review Letters, 2004, 92(1), 017403, Hertel, et al. Applied Physics, 2002, 75(4), 449-465). However, initial time-resolved photoluminescence measurement reveals an extremely rapid excited-state relaxation in CNT bundles (˜1 ps). The rapid decay is attributed to intertube energy transfer from the semiconducting to the metallic nanotubes within each bundle (Lauret, et al. Physcal Review Letters, 2003, 90(5), 057404, Bachilo, Science, 2002, 298, 2361-2366, Hagen, et al. Applied Physics A, 2004, 78, 1137-1145). Surfactants have been used to debundle CNTs and separate semiconducting from metallic tubes. The photoluminescence efficiency was improved and the lifetime was increased up to 200 ps (Hagen, et al., supra, Wang, et al., supra, Araujo, et al., supra, Huang, et al. Physical Review Letters, 2004, 93(1), 17403, Ostojic, et al. Physical Review Letters, 2004, 92, 117402, Hagen, et al. Physical Review Letters, 2005, 95, 197401, Lefebvre, et al. Nano Letters, 2006, 6(8), 1603-1608, Ohno, et al. Nanotechnology, 2006, 17, 549-555). The large disparity between measurements and theoretical predictions has contributions from several aspects.

Defects in individual CNTs can arise during the growth process and post growth treatment (vigorous sonication). The measured recombination time varied from 20 ps to 180 ps for tubes with identical (n, m), further supporting the contention that the exciton dynamics is strongly influenced by defect-induced trap states (Ohno, et al., supra). In addition, the presence of small residual bundles which unavoidability contain metallic tubes quench photoluminescence from semiconducting ones, thereby introducing non-radiative decay channels (Torrens, et al. Nano Letters, 2006, 6(12), 2864-2867).

Besides the aforementioned advantage of using CNTs as a photodetector, the increased electron and hole overlap due to strong Coulombic coupling further enhance photoabsorption intensity. Photon induced current from CNT films has been detected (Berger, et al. Nano Letters, 2007, 7(2), 398-402, Zhao, et al. Physical Review Letters, 2004, 93(15), 157402, Lefebvre, et al. Physical Review B, 2004, 70, 045419). Due to the trap states resulting from the tube-to-tube and tube-to-substrate interactions and the loss of ballistic transport property in CNT film, the photoconductivity yield is low. However, using individual CNTs as the channel in an ambipolar field-effect transistor, the photocurrent has been found to be maximized for photons polarized along the direction of the CNT with an estimated quantum efficiency of greater than 10% (Freitag, et al., supra, Yang, et al. Physical Chemistry Chemical Physics, 2005, 7, 512-517).

The devices disclosed herein comprise nanorods that are (i) suspended without interaction with their underlying material; (ii) high quality to minimize nonradiative recombination channels associated with defects and traps; (iii) semiconducting to eliminate quenching photoluminescence from metal-like nanorods; (iv) electrically isolated to avoid charge transfer; (v) of adjustable diameter; (vi) of tunable density and (vii) in a controlled environment. This invention provides methods to produce optoelectronic devices which can be used as solar cells, photovoltaic cells and photodetectors, for example.

### SUMMARY OF THE INVENTION

This invention provides an optoelectronic device, comprising, or alternatively consisting essentially of, or yet further consisting of the following elements:
at least one first electrode;
at least one second electrode disposed opposite the at least one first electrode, such that a gap is defined between the at least one first electrode and the at least one second electrode; the first and second electrodes optionally positioned on or within a solid base, and
a three-dimensional array of nanorods spanning the gap and wherein at least one nanorod is in contact with the first electrode and the second electrode. In one embodiment, the nanorods are semiconducting nanorods.

In one aspect, the optoelectronic device comprises, or alternatively consists essentially of, or yet further consists of a first electrode stack comprising, or alternatively consisting essentially of, or yet further consisting of, a plurality of stacked, spatially-separated first electrodes; and a second electrode stack comprising, or alternatively consisting essentially of, or yet further consisting of, a plurality of stacked, spatially-separated second electrodes disposed opposite the plurality of first electrodes, such that a gap is defined between the first electrode stack and the second electrode stack. The first electrode stack and the second electrode stack optionally are positioned on or within a solid base. In one aspect, a three-dimensional array of nanorods spans the gap and contacts the first electrode stack and the second electrode stack.

In some embodiments, the optoelectronic device further comprises, or alternatively consists essentially of, or yet further consists of, a catalyst particle-containing matrix layer between neighboring first electrodes in the first electrode stack and a catalyst particle-containing matrix layer between neighboring second electrodes in the second electrode stack.

In some embodiments, the optoelectronic device described above further comprises, or alternatively consists essentially of, or yet further consists of, a layer of insulating material between neighboring first electrodes in the first electrode stack and a layer of dielectric material between neighboring second electrodes in the second electrode stack. The insulating material can be any dielectric material, and is preferably an oxide layer such as silicon dioxide, aluminum oxide or magnesium oxide.

In some embodiments, the optoelectronic device described above further comprising, or alternatively consisting essentially of, or yet further consisting of, a solid base defining an indentation, wherein the at least one first electrode, the at least one second electrode and a three dimensional array of nanorods are at least partially contained within the indentation.

In another aspect, the invention provides an optoelectronic device comprising at least one or a plurality of isolated nanotubes suspended across a gap defined by opposing ends of a substrate. As described in more detail below, the opposing ends of the substrate are, in one embodiment, indented and metal coated. The isolated nanotubes are useful as transducers when a bias is generated across the nanotubes. The bias can be generated by using electrodes comprised of different conductive material having different work functions, or alternatively, using an applied external voltage. The applied external voltage should be sufficient to promote an electron and create the electron hole. In one embodiment, the applied external voltage exceeds about 0.5 eV.

The nanorods can be any one or more of a nanowire or a nanotube such as those defined herein. In one embodiment, the nanorods is a carbon nanotube (“CNT”). The optoelectronic device disclosed herein allows for the fabrication of suspended and pristine carbon nanotubes in the absence of unwanted perturbation. Non-radiative recombination channels (which are due to the interaction with substrates and defects introduced during aggressive sonication) can thus be eliminated. In addition, when suspended and isolated from one another, possible photoluminescence quenching due to the interaction of CNTs with surfactants are avoided.

When the nanorods are arranged on the optoelectronic device disclosed herein, they have a high fill factor and allow for an increased signal which was previously unattainable. In addition, catalyst properties including size, spacing and composition can be adjusted by self-assembled block copolymer templates in the presence of nanoparticles. Suitable catalysts for fabricating substantially uniform sized catalyst particles include, but are not limited to copolymer micelles having a transition metal particle incorporated therein, such as iron, cobalt, and molybdenum in the presence of nickel. In addition, the nanorod growth sites can be controlled by careful deposition of the catalyst particles at predefined locations by use, for example, of a block copolymer template that serves to control the size and spacing of the metal catalyst particles. The deposition of the catalyst-particles can be accomplished via methods known in the art such as spin coating a solution of the catalyst-particles in a matrix as described in Dai et al., U.S. Pat. No. 6,401,526. In certain embodiments, the matrix is a polymer, such as poly(styrene-block-2-vinylpyridine) (PS-b-P2VP). Thus, the size and spacing of the nanorods, such as single-walled carbon nanotubes or nanowires, for example, can be tailored independently layer by layer. Further control, such as horizontal and vertical nanorod density is attained. The density is dictated by catalyst spacing and can be tailored by the catalyst particle containing matrix. Vertical control of nanorod density can be achieved by the amount of catalyst-particles deposited on each of the layers or on the walls of the gap or indentation.

The disclosed optoelectronic devices of this invention are fully compatible with conventional semiconducting device fabrication and therefore can directly be integrated into existing conventional fabrication. In addition, the invention provides a vertically graded bandgap design which can be fabricated using the disclosed device architecture by controlling the diameter of the nanowires from top to bottom. This configuration offers unprecedented absorption cross-section of solar radiation. The variation of tunable bandgap that can be achieved by quantum wells is limited due to strain caused by lattice mismatch. This design circumvents all the aforementioned restrictions. In certain embodiments, the invention provides nanowire-based photovoltaic devices with high solar radiation conversion.

In one aspect, the present invention is directed to a method for producing an electrical current, comprising applying a bias to the optoelectronic devices disclosed herein or by manufacturing the device with the electrodes composed of different metals having different work functions. In at least this aspect of the invention, the optoelectronic devices can be used as an energy source.

The devices of this invention are multi-functional optoelectronic devices. The devices can use CNTs for near-infrared detection for night surveillance and convert solar energy into electricity in the day time. Further, the disclosed devices have the potential for use as an uncooled and self-powered broad-band photodetector with enhanced sensitivity.

In addition, the devices utilize the extremely large surface area offered by CNTs, which is desirable for many applications such as sensors and photodetectors, as a high population density of CNTs is required in a single device. Hence, many applications which demand the rational three dimensional control of CNT density can be fabricated.

### BRIEF DESCRIPTION OF THE DRAWINGS

FIGS. 1A and 1B show fabrication steps for a layered optoelectronic device having a solid base 10, insulating layers 11, catalyst-particle polymer layers 12, and metal (electrode) layers 13. FIG. 1B shows the nanorods 15 suspended across the indentation and the isolated metal contacts 14. FIG. 1C is a band diagram.

FIGS. 2A through 2D show fabrication steps for an optoelectronic device. FIG. 2A shows a solid base 10 having an insulating layer 11 and nanorods 15 surrounded by a dielectric material 16. FIG. 2B shows a photomask 20 which allows for selective removal of the dielectric material 16 to expose the ends of the nanorods 15. FIG. 2C shows the electrodes 13. FIG. 2D shows an alternate configuration.

FIG. 3A shows a nanorod 15 surrounded by a dielectric material 16 (a surfactant is shown). FIGS. 3B and 3C show optoelectronic devices wherein the nanorods 15 are aligned using an electrical source and immobilized using a dielectric material 16.

FIG. 4A is a series of SEM images of suspended nanotubes across a gap or indentation of an optoelectronic device substrate. FIG. 4B is a schematic of the formation of the indentation, catalyst deposition, nanorod growth, and electrode deposition. FIG. 4C is a schematic of optoelectronic devices comprising nanowires and nanorods of different composition.

FIGS. 5A through 5K shows the fabrication of an optoelectronic device comprising a series of plateau regions. FIG. 5A shows a solid base 10 having an insulating layer 11, a catalyst-particle polymer layer 12, and suspended nanorods 15. FIG. 5B shows the deposition of a dielectric material 16 using atomic layer depostion. FIG. 5C shows the chemical mechanical polishing of the dielectric material 16. FIGS. 5D through 5F show the use of a photomask 20 with lithography or etching to provide a column of coated suspended nanorods 15. FIG. 5G shows patterning and plating of the electrodes 13. FIG. 5H shows the optoelectronic device.

FIGS. 6A through 6C show fabrication steps for a layered optoelectronic device having a solid base 10, insulating layers 11, catalyst-particle polymer layers 12, and metal (electrode) layers 13. FIG. 6B shows the formation of the isolated metal contacts 14 and the indentation or gap which can be formed by etching to expose the catalyst-particle polymer layers 12. FIG. 6C shows the optoelectronic device having nanorods 15 suspended across the indentation.

FIGS. 7A and B, show P4VP and P2VP with and without addition of FeCl₂-4H₂O. FIG. 7A shows the AFM height images of P4VP and P2VP with the addition of FeCl₂-4H₂O (scan area: 1 by 1 μm, height: 5 nm) and FIG. 7B shows FTIR spectra with pure P4VP and P2VP with and without addition of FeCl₂-4H₂O (spectra was offset for clarification).

FIG. 8 shows a representative AFM height image of Fe nanoparticles (scan area: 3 by 3 μm, height: 5 nm).

FIGS. 9A and 9B, show SEM images of substrates after CNT growth. FIG. 9A shows representative tilted SEM images of substrates after CNT growth and FIG. 9B shows representative cross-section SEM images of substrates after CNT growth (the black arrows highlight the anchoring points of the CNTs to the sidewalls).

FIG. 10 shows typical Raman spectra of suspended CNTs at Radial breathing region (left) and in-plane graphene oscillation region (right). The inset is top-down SEM of suspended CNTs used for Raman analysis.

FIG. 11 shows SEM images which show that tube orientation is induced by surface topography. The suspended CNTs were synthesized from patterned surfaces with neighboring trenches oriented substantially perpendicularly. It can be seen that suspended CNTs are oriented substantially orthogonally the sidewalls of trenches and are substantially parallel with each other.

### DETAILED DESCRIPTION OF THE INVENTION

As used herein, certain terms may have the following defined meanings.

As used in the specification and claims, the singular form “a,” “an” and “the” include singular and plural references unless the context clearly dictates otherwise. For example, the term “a carbon nanotube” includes a single carbon nanotube and as well as a plurality of carbon nanotubes.

As used herein, the term “comprising” is intended to mean that the compositions and methods include the recited elements, but do not exclude others. “Consisting essentially of” when used to define compositions and methods, shall mean excluding other elements of any essential significance to the combination when used for the intended purpose. Thus, a composition consisting essentially of the elements as defined herein would not exclude trace contaminants or inert carriers. “Consisting of” shall mean excluding more than trace elements of other ingredients and substantial method steps for preparing the molecular sensor. Embodiments defined by each of these transition terms are within the scope of this invention. Accordingly, it is intended that the methods and compositions can include additional steps and components (comprising) or alternatively including the steps and compositions of no significance (consisting essentially of) or alternatively, intending only the stated methods steps or compositions (consisting of).

An “optoelectronic device” intends a device or material that either produces light or uses light in its operation. Examples of optoelectronic devices include, but are not limited to, light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like.

As used herein the term “nanotube” is intend to mean a cylindrical tubular structure of which the most inner diameter size lies between 0.5 nm and 1000 nm. Various types of nanotubes can be used in the optoelectronic device disclosed herein. Preferred nanotubes to be used in the optoelectronic device disclosed herein are semiconducting nanotubes.

In one embodiment, the nanotubes are carbon nanotubes. A “carbon nanotube” is a member of the fullerene structural family, which also includes buckyballs. Whereas buckyballs are spherical in shape, a carbon nanotube is cylindrical, with at least one end typically capped with a hemisphere of the buckyball structure. Carbon nanotubes are composed primarily or entirely of sp² bonds, similar to those of graphite. This bonding structure, stronger than the sp³ bonds found in diamond, provides the molecules with their unique strength. Single-walled CNTs (SCNT) or multi-walled CNTs (MCNTs) are examples of well-studied CNT structures.

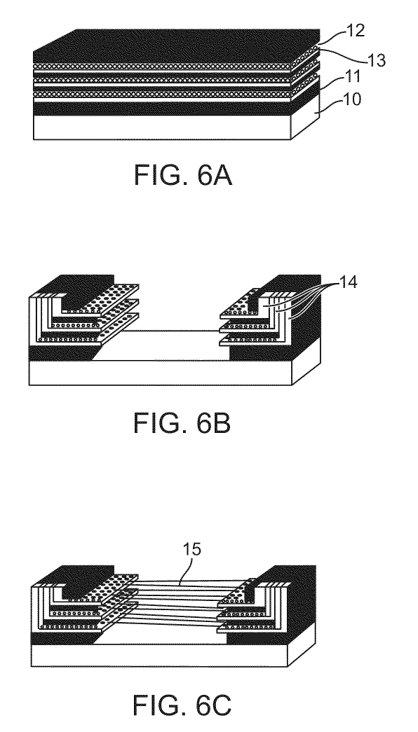

As used herein the term “suspended carbon nanotube” is intend to mean a carbon nanotube suspended across an indentation of a solid support. The term “solid support” is intend to mean a catalyst-containing template as shown in FIG. 6, on which suspended CNTs can be grown. The terms “catalyst” and “catalyst-particle” are used interchangeably and are intended to refer to a carbon-nanotube-growth-promoting or nucleating-catalyst, such as those containing iron, cobalt, or any other suitable carbon-nanotube-growth-promoting or nucleating-catalyst or mixture thereof. The size of the catalyst-particles on the “solid support” control the diameter of the suspended carbon nanotubes. The synthesis of suspended carbon nanotubes on such support structures that can be used in the present invention include, but are not limited to those which are known in the art (Lu, et al. J. Phys. Chem. B. 2006, 110, 10585-10589; Cassell, et al. J. Am. Chem. Soc. 1999, 121, 7975-7976). The suspended nanotubes synthesized on the support structures of the disclosed invention are to be differentiated from the vertically aligned or bundled nanotubes known in the art (Zhao, et al. US Pub. No. US 2006/0252065, filed Mar. 5, 2006).

As used herein, the term “nanowire” is intend to mean a wire of diameter of the order of a nanometer (10⁻⁹ meters). Alternatively, nanowires can be defined as structures that have a lateral size constrained to tens of nanometers or less and an unconstrained longitudinal size. At these scales, quantum mechanical effects are important, therefore such wires are also referred to as “quantum wires”. Many different types of nanowires exist, including metallic (e.g., Ni, Pt, Au), semiconducting (e.g., Si, InP, GaN, etc.), and insulating (e.g., SiO₂,TiO₂). Molecular nanowires are known and are composed of repeating molecular units of either organic (e.g. DNA) or inorganic compounds. Nanowires to be used in the optoelectronic device disclosed herein are semiconducting nanowires.

As used herein, the term “nanorod” includes nanowires and nanorods and refers to a nanoscale object, including, having dimensions in the range of from about 1 nanometer to about 100 nanometers. Nanorods can comprise a variety of elements including, but not limited to, zinc, gallium, cadmium, copper, titanium, indium, calcium, gold, magnesium, iron, indium, silicon, vanadium, carbon, boron, bismuth, germanium, and mixtures thereof. Non-limiting examples of nanorods include gallium phosphide, gallium arsenide, gallium nitride, zinc oxide, zinc sulfide, cadmium oxide, cadmium sulfide, cadmium selenide, copper oxide, titanium dioxide, indium phosphide, indium arsenide, indium oxide, indium tin oxide, aluminum nitride, magnesium oxide, silicon carbide, vanadium oxide, boron nitride, and the like. The composition of the nanorods can be controlled using methods well known to those of skill in the art, including catalyst composition, feed gas, and the like, as described in Islam et al. U.S. Pat. Nos. 7,307,271; 7,208,094; 7,344,961; 7,105,428; 7,087,920; or 6,962,823. It may be that devices comprising nanorods of a given composition can be used to convert various types of energy to electrical energy. For example, zinc oxide nanorods can be used to transfer mechanical energy to electrical energy, whereas silicon nanorods can be used to transfer heat to electrical energy.

As used herein, the term “transducer” is intend to mean a species that converts a signal from one form to another, such as optical-to-electrical transducers, to allow current flow.

An “electrode” intends a conductive material containing movable electronic charges that is used to make a contact with a non-metallic part of a circuit such as a semiconductor, an electrolyte or a vacuum. Conductive materials include, but are not limited to metallic conductors such as gold, palladium, platinum, molybdenum, titanium, copper, silver, lead, zinc or aluminum and non-metallic substances such as carbon.

A “semiconductor” refers to a solid material that has electrical conductivity between a conductor and an insulator, which can vary over a wide range either permanently or dynamically. Semiconducting materials can be made in whole or in part from materials such as silicon, germanium, gallium arsenide, indium phosphide, silicon germanium or aluminum gallium arsenide. In certain embodiments, the nanorods are semiconducting nanorods. Therefore, as disclosed, the nanorods can comprise any of the materials as defined, such as zinc, gallium, cadmium, copper, titanium, indium, calcium, gold, magnesium, iron, indium, silicon, vanadium, carbon, boron, bismuth, germanium, and mixtures thereof.

An “electrode stack” intends a plurality of electrodes separated by at least an insulating layer. The electrode stack can comprise conducting elements, such as a metal. One or more different conducting elements may be used in various layers of the electrode stack.

As used herein, “bandgap” intends the energy difference between the top of a valence band and the bottom of a conductance band.

The following abbreviations are used throughout this disclosure.
° C.=degrees Celsius
AFM=atomic force microscopy/atomic force microscope
CNT=Carbon nanotube
CVD=chemical vapor deposition
ICP=inductively coupled plasma
IR=Infrared spectroscopy
FTIR=Fourier transform infrared spectroscopy
M=Meter
min=Minute
μm=Micrometer
MWCNT=multi-walled carbon nanotube
nm=Nanometer
Ns=Nanosecond
PL=Photoluminescence
Ps=Picosecond
PS-b-P2VP=polystyrene-b-poly(2-vinylpyridine)
PS-b-PFEMS=polystyrene-b-polyferrocenylethylmethylsilane
rpm=revolutions per minute
s=Second
Sccm=Standard Cubic Centimeters per Minute, where “Standard” means referenced to 0° C. and 760 Torr.
SEM=scanning electron microscope
SWCNT=single-walled carbon nanotube
TEM=transmission electron microscopy
XPS=X-ray photoelectron spectroscopy

All numerical designations, e.g., pH, temperature, time, concentration, and molecular weight, including ranges, are approximations which are varied (+) or (−) by increments of 0.1. It is to be understood, although not always explicitly stated that all numerical designations are preceded by the term “about”. The term “about” also includes the exact value “X” in addition to minor increments of “X” such as “X+0.1” or “X−0.1.” It also is to be understood, although not always explicitly stated, that the reagents described herein are merely exemplary and that equivalents of such are known in the art.

### An Optoelectronic Device Comprising a Three-Dimensional Array of Semi-Conducting Nanorods

The optoelectronic device disclosed herein is fully compatible with conventional semiconducting device fabrication. In one aspect, this invention provides optoelectronic devices useful as light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like, depending on the composition of the nanorods. The optoelectronic device contains at least one first electrode and at least one second electrode disposed opposite the at least one first electrode disposed on a solid base, such that a gap is defined between the at least one first electrode and the at least one second electrode. Suspended within the gap and bridging the first electrode and the second electrode is a three dimensional array of nanorods, wherein at least one of the suspended nanorods is in contact with the opposite first electrode and the second electrode.

Nanorods are nanoscale objects having dimensions in the range of from about 1 nanometer to about 100 nanometers. Nanorods can comprise a variety of elements including, but not limited to, zinc, gallium, cadmium, copper, titanium, indium, calcium, gold, magnesium, iron, indium, silicon, vanadium, carbon, boron, bismuth, germanium, and mixtures thereof. Non-limiting examples of nanorods include gallium phosphide, gallium arsenide, gallium nitride, zinc oxide, zinc sulfide, cadmium oxide, cadmium sulfide, cadmium selenide, copper oxide, titanium dioxide, indium phosphide, indium arsenide, indium oxide, indium tin oxide, aluminum nitride, magnesium oxide, silicon carbide, vanadium oxide, boron nitride, and the like. The composition of the nanorods can be controlled using methods well known to those of skill in the art, including catalyst composition, feed gas, and the like, as described in Islam et al. U.S. Pat. Nos. 7,307,271; 7,208,094; 7,344,961; 7,105,428; 7,087,920; or 6,962,823. Nanorods can be either conducting or semiconducting. In one embodiment, the nanorods are semiconducting nanorods.

The electrodes are composed in whole or in part of a conductive material, preferably a metal. Non-limiting examples of suitable metals include, but are not limited to gold, palladium, platinum, molybdenum, titanium, copper, silver, lead, zinc or aluminum. The electrodes may be composed of the same or different conductive material each other. In order to create a bias across the semiconducting nanorods, it is contemplated that either a bias must be applied or the first and second electrode have a different band gap. Therefore, in some embodiments, the first and second electrodes comprise a different metal composition to create the necessary bias. Such optoelectronic devices are useful as light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like.

The diameter of the nanorods can range from about 0.5 to about 100 nm. In one aspect, the nanorods have an diameter of less than about 100 nm, or alternatively, less than about 50 nm, or alternatively, less than about 25 nm, or alternatively, less than about 10 nm, or alternatively, less than about 2 nm, or alternatively, less than about 1.8 nm, or alternatively, less than about 1.6 nm, or alternatively, less than about 1.4 nm, or alternatively, less than about 1.2 nm, or alternatively, less than about 1.0 nm, or alternatively, less than about 0.8 nm. The nanorods can be any nanorods, nanotube or nanowire as disclosed herein, and can comprise zinc, gallium, cadmium, copper, titanium, indium, calcium, gold, magnesium, iron, indium, silicon, vanadium, carbon, boron, bismuth, germanium, and mixtures thereof. Materiality and dimensionality of nanorods, nanotubes and nanowires are disclosed above and is incorporated herein by reference.

The solid base can comprise in whole or in part of a material, such as silicon, that is either non-conductive or can be otherwise converted into a non-conductive material. For example, the solid base can comprise silicon, wherein thermal deposition of silicon oxide gives a non-conductive surface. Other materials which can be used include, for example, silicon, germanium, gallium arsenide, indium phosphide or plastic.

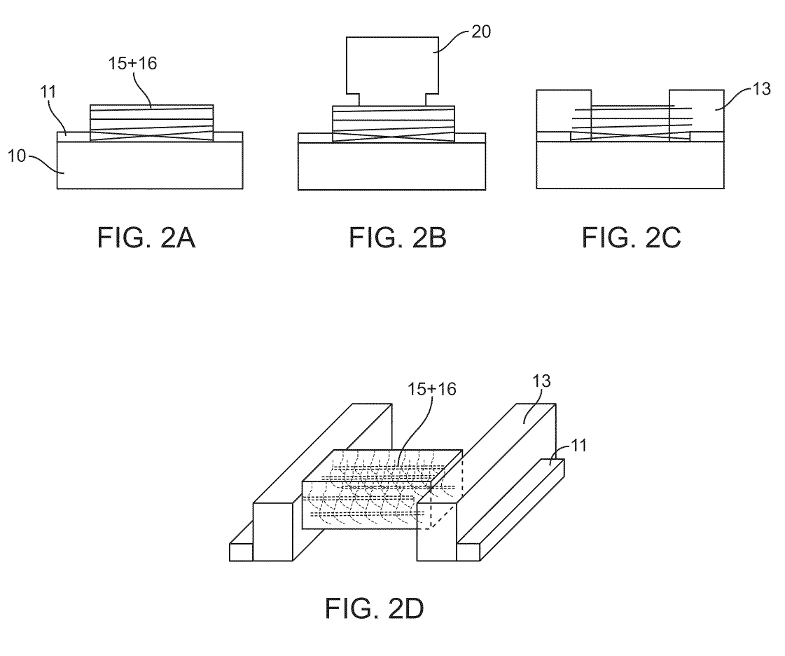

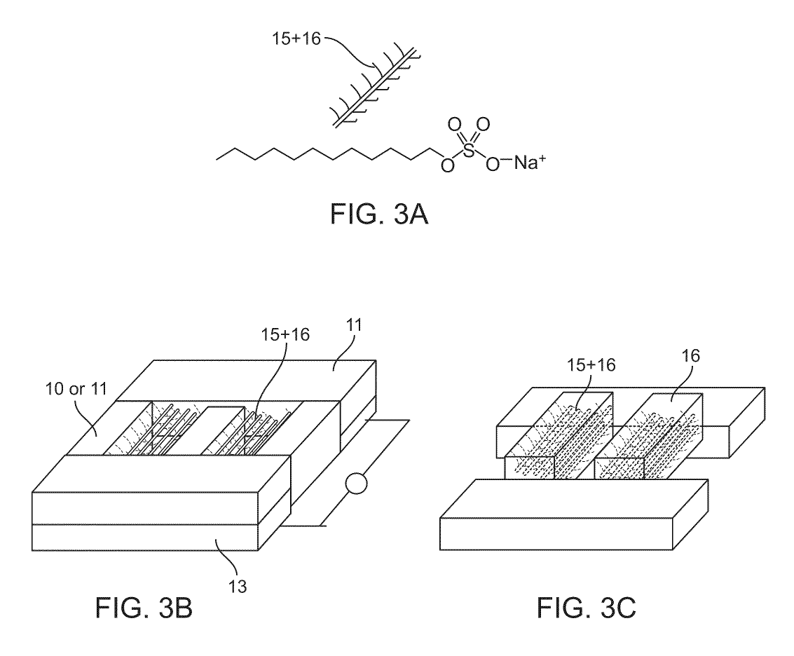

The gap or indentation are intended to refer to a concave depression or cut on a surface. The indentation or gap as disclosed herein can be of any possible shape, size or design, e.g., without limitation a trench or well. The indentation or gap can be produced using a number of known methods, such as photolithography, soft lithography, isotropic or anisotropic etching, or with the use of a mold. Such technologies are well known in the art (Xia, et al., Angew. Chem. Int. Ed., 1998, 37, 550-575). Alternatively, the indentation or gap is generated by depositing the electrodes at a position relative to each other such that a substantially large space is between them. Depending on the stage of production, device design and intended use, the gap or indentation can be a void and therefore comprise air, nitrogen, or a vacuum, or alternatively comprise a solution, a surfactant or filled with a polymer or the like. In one embodiment, a surfactant may be used to prevent pre-synthesized nanorods from contacting each other during the fabrication process (see FIGS. 3A and 3B, for example). In another embodiment, a polymer may be used to immobilize the nanorods (see FIGS. 2, 3C and 6, for example).

The nanorods can be comprised of any suitable material, such as without limitation zinc, gallium, cadmium, copper, titanium, indium, calcium, gold, magnesium, iron, indium, silicon, vanadium, carbon, boron, bismuth, germanium, and mixtures thereof, and are contained within the gap of a predetermined dimension. For the devices and methods disclosed herein, the indentation or gap may be about 10 μm wide. In one embodiment, the indentation or gap is less than about 10 μm. In an alternative embodiment, the indentation or gap is about 9 μm, or alternatively, about 8 μm, or alternatively, about 7 μm, or alternatively, about 6 μm, or alternatively, about 5 μm, or alternatively, about 4 μm, or alternatively, about 3 μm, or alternatively, about or greater than about 2 micrometers. The length of the nanorod or plurality of nanorods is approximately equal to the dimensions of the gap or indentation.

In one aspect, the device contains a plurality of first electrodes and a plurality of second electrodes, each positioned relative to each other such that they are spatially separated to define at least a first electrode stack and a second electrode stack. Thus, this invention also provides an optoelectronic device comprising a first electrode stack comprising a plurality of spatially-separated electrodes and a second electrode stack, also comprising a plurality of spatially-separated electrodes. The first and second electrode stacks are disposed opposite each other such a gap is defined there between.

The electrodes can be comprised of any suitable material, for example palladium, gold or platinum and are generally about 0.2 μm to about 2.0 μm wide. In some embodiments, the electrodes are about 0.2 μm wide, or alternatively, about 0.5 μm wide, or alternatively, about 0.8 μm wide, or alternatively, about 1 μm wide, or alternatively, about 1.2 μm wide, or alternatively, about 1.5 μm wide, or alternatively, about 1.8 μm wide, or alternatively, about 2.0 μm wide. Further, the electrodes have a thickness of about 0.1 μm to about 1 μm. In some embodiments, the electrodes have a thickness of about 0.1 μm, or alternatively, about 0.3 μm, or alternatively, about 0.5 μm, or alternatively, about 0.8 μm, or alternatively, about 1 μm. In general, the electrodes can be as small as possible.

In one aspect, suspended within the gap and bridging the first electrode and the second electrode is a three dimensional array of suspended nanorods, wherein at least one suspended nanorods contacts the first electrode and the second electrode. The diameter of the nanorods range from about 0.5 nm to about 100 nm. In one aspect, the nanorods have an internal diameter of less than about 100 nm, or alternatively, less than about 50 nm, or alternatively, less than about 25 nm, or alternatively, less than about 10 nm, or alternatively, less than about 2 nm, or alternatively, less than about 1.8 nm, or alternatively, less than about 1.6 nm, or alternatively, less than about 1.4 nm, or alternatively, less than about 1.2 nm, or alternatively, less than about 1.0 nm, or alternatively, less than about 0.8 nm.

The nanorods can be comprised of any suitable material, such as without limitation, zinc, gallium, cadmium, copper, titanium, indium, calcium, gold, magnesium, iron, indium, silicon, vanadium, carbon, boron, bismuth, germanium, and mixtures thereof. The composition, size and/or dimensions of the nanorods can be the same or different from each other. These characteristics can be controlled by the use of materials and fabrication methods as described herein.

The indentation or gap may be about or less than about 10 μm wide. When less than about 10 μm wide, the indentation or gap is about 9 μm, or alternatively, about 8 μm, or alternatively, about 7 μm, or alternatively, about 6 μm, or alternatively, about 5 μm, or alternatively, about 4 μm, or alternatively, about 3 μm, or alternatively, about or greater than about 2 micrometers.

In one aspect of the devices having a first electrode stack and a second electrode stack, the optoelectronic device further contains a catalyst particle-containing matrix layer deposited between neighboring first electrodes in the first electrode stack and a catalyst particle-containing matrix layer deposited between neighboring second electrodes in the second electrode stack. Suitable catalyst particle-containing material includes, but is not limited to nanorods, nanowire or nanotube forming catalysts. Such catalysts are to known to those of skill in the art and include for example, transition metals. Methods for generating specially separated and uniformly sized catalyst nanoparticles are disclosed herein and include the use of a copolymer matrix which forms micelles around the transition metal nanoparticle. The thickness of the catalyst particle-containing matrix layer deposited is from about 20 nm to about 40 nm. In some embodiments, the catalyst particle-containing matrix layer deposited is from about 20 nm, or alternatively, about 25 nm, or alternatively, about 30 nm, or alternatively, about 35 nm, or alternatively, about 40 nm. After the catalyst particle-containing matrix layer is deposited and the nanoparticles are exposed (usually by heating), the height of the spatially separated nanoparticles is from about 2 nm to about 5 nm, or alternatively, about 2 nm, or alternatively, about 3 nm, or alternatively, about 4 nm, or alternatively, about 5 nm.

Optoelectronic devices having first and second electrode stacks and at least one catalyst-particle containing matrix are useful as a magnetic hard disk or hard drive. It is contemplated that the catalyst nanoparticles have metallic properties and thus the optoelectronic device substrates containing the catalyst nanoparticles can be used for recording devices.

In a further aspect, the optoelectronic device further comprises a layer of insulating material between neighboring first electrodes in the first electrode stack and/or a layer of insulating material between neighboring second electrodes in the second electrode stack. The insulating material can be comprised of a dielectric material which includes, but is not limited to silicon dioxide, aluminum oxide, magnesium dioxide, or other metal oxide, for example, and is deposited in a layer of about 5 nm to about 0.2 μm. In one embodiment, the insulating layer is about 5 nm, or alternatively, about 10 nm, or alternatively, about 50 nm, or alternatively, about 100 nm, or alternatively, about 300 nm, or alternatively, about 500 nm, or alternatively, about 750 nm, or alternatively, about 0.1 μm, or alternatively, about 0.2 μm. In one embodiment, the first electrode stack and the second electrode stack further comprises an isolated metal contact. The isolated metal contact would increase the surface area of the first and second electrodes in the stacked configuration.

Optoelectronic devices having first and second electrode stacks, at least one catalyst-particle containing matrix, and dielectric material are useful as useful as a magnetic hard disk or hard drive. It is contemplated that the catalyst nanoparticles have metallic properties and thus the optoelectronic device substrates containing the catalyst nanoparticles can be used for recording devices.

In each of the above described optoelectronic devices described above, the device can further comprise a solid base defining an indentation, wherein the at least one first electrode, the at least one second electrode, and the three dimensional array of nanorods are at least partially contained within the indentation. In some embodiments, the gap is an indentation. Optoelectronic devices having an indentation are useful as useful as a magnetic hard disk or hard drive. It is contemplated that the catalyst nanoparticles have metallic properties and thus the optoelectronic device substrates containing the catalyst nanoparticles can be used for recording devices.

The geometry or shape of the indentation or gap can be any geometry. For example, it can be a trench or well, and contain a series of levels therein which can be the same or of uniform dimension or alternatively, varying dimensions. The indentations can vary and can be less than about 10 μm, or alternatively less than 8 μm, or yet further less than about 5 μm. In a certain embodiment, the optoelectronic device of the invention has a solid base having an indentation where the walls of the indentation are coated with an insulating layer and over-coated with a catalyst particle-containing matrix layer.

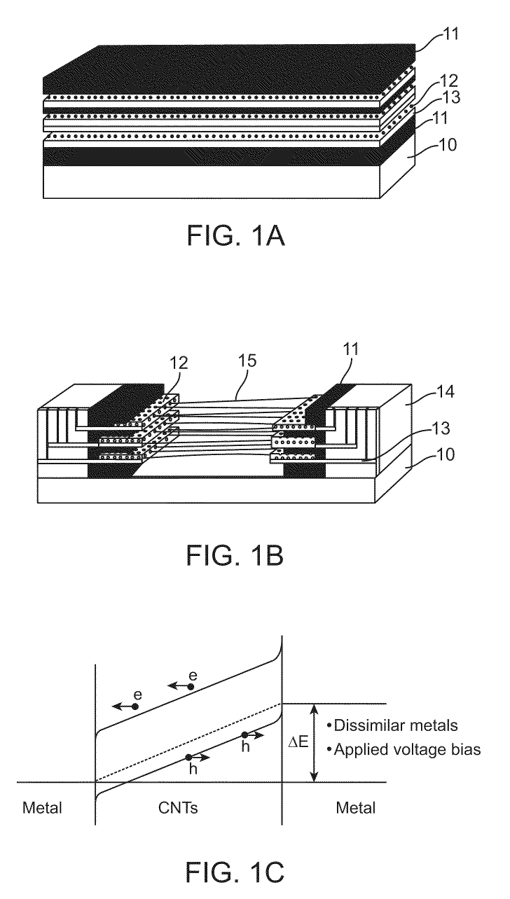

In one embodiment, the opposing surfaces of the at least one first electrode and the at least one second electrode have a semi-circular profile. The electrodes are composed in whole or in part of a conductive material, preferably a metal, which may be the same or different from each other. Non-limiting examples of suitable metals include, but are not limited to gold, palladium, platinum, molybdenum, titanium, copper, silver, lead, zinc or aluminum. In order to create a bias across the semiconducting nanorods, it is contemplated that either an external bias must be applied or the first and second electrode comprise conductive material having a different band gap (FIG. 1C). Therefore, in some embodiments, the first and second electrodes comprise a different metal composition to create the necessary bias. Such optoelectronic devices are useful as light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like.

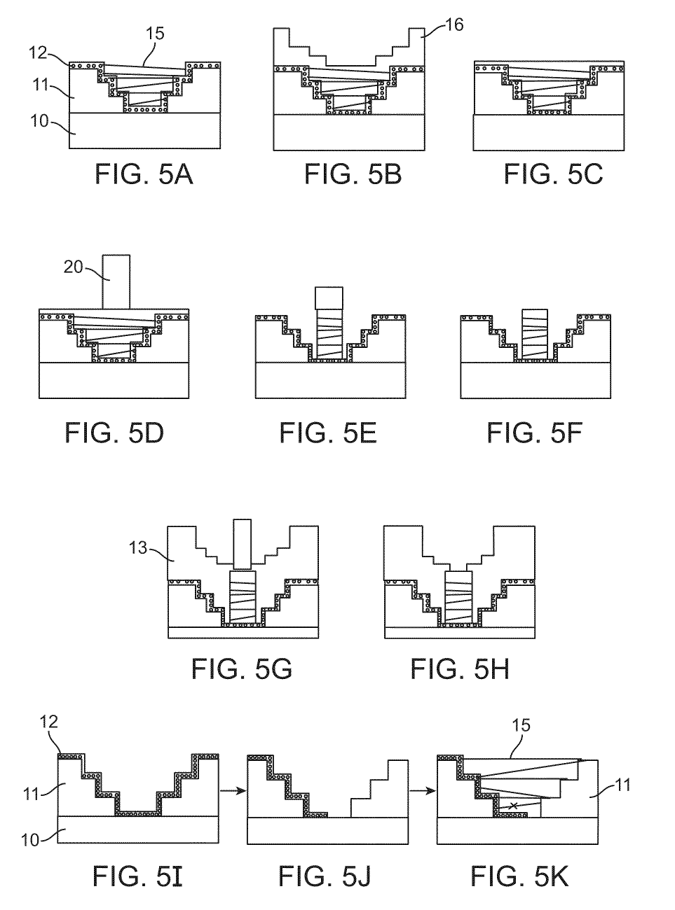

Referring to FIG. 5, in certain embodiments, the optoelectronic device substrate may further contain a series of plateau regions of sizes ranging from a depth of about 50 nm to about 200 nm and a width of about 50 nm to about 500 nm. In one aspect, the depth is less than about 200 nm, or alternatively less than about 150 nm, or yet further less than about 100 nm. Additionally, in one aspect, the with is less than about 500 nm, or alternatively less than about 400 nm, or alternatively less than about 300 nm, or alternatively less than about 200 nm, or yet further less than about 100 nm. The series of plateau regions can resemble two adjacent staircases which face each other. Alternatively, only one side of the indentation or series of plateau regions contain a catalyst particle-containing matrix layer which is exemplified in FIG. 5, panels I-K. This configuration can be generated using methods know in the art, such as top-down lithography, and subsequent etch, described for example in Fujii, et al. U.S. Publication No. 2007/0207274A1 (application Ser. No. 11/712,481); Xia, et al. Langmuir, 2007, 23(10), 5377-5785; Yang et al. (The Chemistry of Nanostructured Materials (World Scientific Pub Co, 2003)) and Nalwa et al. (Handbook of Nanostructured Materials and Nanotechnology (Academic Press, 2000). FIG. 5A shows a solid base 10 having an insulating layer 11 which is over-coated with a catalyst-particle polymer layer 12. The suspended nanorods 15 then bridge the indentation. FIG. 5B shows the deposition of a dielectric material 16 using atomic layer deposition. FIG. 5C shows the chemical mechanical polishing of the dielectric material 16 to provide an even surface. FIGS. 5D through 5F show the use of a photomask 20 with lithography or etching to provide a column of suspended nanorods 15 which are surrounded with a dielectric material 16. FIG. 5G shows patterning and plating of the electrodes 13. FIG. 5H shows the optoelectronic device. A conforming catalyst-containing polymeric film can be achieved on a properly treated surface partially due to the fact that a high molecular weight polymeric material is employed. Well-defined catalyst arrays need to be formed on the plateau regions.

In one aspect, the insulating layer of the optoelectronic device substrates is over-coated with a catalyst particle-containing matrix layer in an amount effective to facilitate the growth of the nanorods. In certain embodiments, the nanorods are grown on the optoelectronic device substrate in situ.

Optoelectronic devices containing the indentation or series of plateau regions having a catalyst particle-containing matrix layer can be used as a magnetic hard disk or hard drive. It is contemplated that the catalyst nanoparticles have metallic properties and thus the optoelectronic device substrates containing the catalyst nanoparticles can be used for recording devices.

In one embodiment, the solid base 10 of the optoelectronic devices disclosed herein are made in whole or in part of a material such as silicon, germanium or gallium arsenide. In certain embodiments, the solid base further comprises an insulating layer 11 on the surface of the solid base in an amount effective to impede the transfer of electrical current. In certain embodiments, the insulating layer of the optoelectronic device substrate is an oxide layer. Various oxidic materials can be employed as the insulating layer. For example, the oxide layer can comprise Al₂O₃, MgO, or SiO₂. The simplest insulator that can be used with the optoelectronic device substrate is SiO₂.

A metal layer 13 can be deposited on the insulating layer to provide electrodes. It is contemplated that the metal layer 13 could be deposited in a thickness from about 50 nm to about 0.1 μm. In some embodiments, the thickness is greater than about 50 nm, or alternatively, about 100 nm, or alternatively, about 200 nm, or alternatively, about 300 nm, or alternatively, about 400 nm, or alternatively, about 500 nm, or alternatively, about 600 nm, or alternatively, about 700 nm, or alternatively, about 800 nm, or alternatively, about 900 nm, or alternatively, less than about 0.1 μm. The metal layer can be any metal or metal alloy capable of conducting a current. The metal layer can be formed by using standard micro fabrication processing as described in Khoury, U.S. Pat. No. 6,255,727; Atencia, et al. Nature, 2005, 437, 648-655; Lee, et al. Anal. Chem. 2005, 77(16), 5414-5420. Specific metals which can be used as the metal layer include, but are not limited to gold, palladium, platinum, a gold alloy, a palladium alloy, or a platinum alloy. Devices with this configuration are useful as light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like.

The geometry or shape of the indentation of the optoelectronic device substrates can be any possible geometry. For example, the indentation can be in the shape of a trench, a well, and contain a series of levels therein. In one embodiment, the indentation has a step-shaped cross-sectional profile. In another embodiment, the indentation has sloped sidewalls, such that the indentation is wider at its mouth than at its base. In addition, with the multilayered optoelectronic device substrate, the various layers of the substrate can be etched selectively using various etching methods as well as various etchants. For example, the indentations can be created by anisotropic etch and followed by an isotropic etch to partially remove the insulating layers for uncovering nanocatalysts. Anisotropically etching methods are well known, and include for example, SF₆, HF or other fluorine or chlorine containing gas as described in Kojima, et al. U.S. Pat. No. 5,445,709.

In reference to each embodiment where an indentation or gap is discussed, they can be fabricated using a number of known methods, such as photolithography, soft lithography, isotropic or anisotropic etching, or with the use of a mold. Such technologies are known in the art and described for example in Xia, et al., Angew. Chem. Int. Ed., 1998, 37, 550-575. Alternatively, the indentation or gap can be a result of depositing the electrodes at a position relative to each other such that a substantially large space is between them. Depending on the stage of production and the device design, the gap or indentation can be filled with air, dry air, nitrogen gas, a vacuum, a solution, a surfactant, a polymer, porcelain, ceramic, mica, glass, plastic, a metal oxide, distilled water, or the like. Suitable solutions include but are not limited to electrolytic solutions, such as water and sodium hydroxide, ionic liquids or a polymer electrolyte solution, such as a polyethylene glycol or hydroxyethylmethacrylate based polymer electrolyte solution. Such solutions are well known in the art (see, for example, Strange et. al. U.S. Pat. No. 6,287,630). Suitable surfactants include, but are not limited to sodium dodecyl sulfate, ammonium lauryl sulfate, sodium laureth sulfate, alkyl benzene sulfonate, cetyl trimethylammonium bromide or cetylpyridinium chloride. Suitable polymers include but are not limited to polystyrene, polyacrylic acid or polyimide based polymers. Devices utilizing the above are useful as light-emitting diodes, photoabsorbers, photodetectors, photovoltaic cells, a plurality of the photovoltaic cells can be used to generate a photovoltaic array, solar cells, photomultiplier tubes, photoresistors, tunable IR emitters, fluorescence-based chemical detectors, and the like.

In general, the indentation or gap contains the three-dimensional array of suspended nanorods. For the devices and methods disclosed herein, the indentation or gap should be about 10 μm wide. In one embodiment, the indentation or gap is less than about 10 μm. In an alternative embodiment, the indentation or gap is about 9 μm, or alternatively, about 8 μm, or alternatively, about 7 μm, or alternatively, about 6 μm, or alternatively, about 5 μm, or alternatively, about 4 μm, or alternatively, about 3 μm, or alternatively, greater than about 2 micrometers.

The indentations of the optoelectronic device enable the synthesis of isolated, suspended nanorods that connect the first and second electrodes or first and electrode stacks. In one aspect, at least a portion of the nanorods bridge the indentation. The nanorods can be comprised of any suitable material, such as without limitation, zinc, gallium, cadmium, copper, titanium, indium, calcium, gold, magnesium, iron, indium, silicon, vanadium, carbon, boron, bismuth, germanium, and mixtures thereof. In one aspect, the nanorods are nanowires. In another aspect, the nanorods are nanotubes. Various nanotubes can be employed in the optoelectronic device. Preferably, the nanotubes are semi-conducting nanotubes. In certain embodiments, the nanotubes are selected from the group consisting of carbon nanotubes, metal oxide nanotubes, boron nitride nanotubes, copper nanotubes, bismuth nanotubes, fullerene analogs and other nanotube analogs. Various metal oxide nanotubes include, for example, vanadium oxide, zinc oxide and manganese oxide. Methods to make such nanotubes are known in the art and described, for example, in Cao, et al. Adv. Colloid. Interface Sci. 2008, 136(1-2), 45-64; Govindaraj, et al. J. Nanosci. Nanotechnol. 2007, 7(6), 1695-702; Goldberger, et al. Acc Chem Res. 2006, 39(4), 239-48. In a particular embodiment, the nanotubes are SWCNTs.

In one embodiment, the optoelectronic devices disclosed herein comprise a catalyst particle-containing matrix layer between the solid base and at least one of the first or second electrodes. In a certain embodiment, the catalyst is a particulate carbon nanotube growth-promoting catalyst. The composition of catalyst can be tailored to yield nanorods with the desired characteristics. For example, the diameter, composition, homogeneity, and other characteristics can be at least partially controlled by controlling the catalyst. In some embodiments, the catalyst is a nanorod forming catalyst such as a transition metal catalyst. Nonmetal catalyzed growth is also known. A typical nonmetal catalyst material is SiOₓ, where x ranges from about 1 to less than 2, for example. Typical nanoparticle catalysts corresponding to titanium and gold catalyst materials, for example, are respectively titanium disilicide and gold-silica alloy. In some embodiments, the catalyst is a nanowire forming catalyst such as titanium, gold, iron, cobalt, gallium, and alloys thereof. In some embodiments, the catalyst is a carbon nanotube forming catalyst such as iron, cobalt, and molybdenum in the presence of nickel. Methods to make such nanorods, nanowires, or nanotubes are known in the art and described for example, in Islam et al. U.S. Pat. Nos. 7,307,271, 7,208,094, 7,344,961, 7,105,428, 7,087,920, or 6,962,823; Cao, et al. Adv. Colloid. Interface Sci. 2008, 136(1-2), 45-64; Govindaraj, et al. J. Nanosci. Nanotechnol. 2007, 7(6), 1695-702; Goldberger, et al. Acc Chem Res. 2006, 39(4), 239-48.

In some embodiments, the length of the nanorods is controlled by the reaction conditions used to synthesize the nanorods, such as time or temperature. The size of the indentation or gap will therefore need to be adjusted accordingly. However, in some embodiments, the length of the nanorods can be controlled by the size of the indentation or gap. In one embodiment the nanorods are carbon nanotubes. To minimize structural inhomogeneity along a carbon nanotube, the maximum length of a tube suspended across a trench will be designed to be about 10 μm. In one embodiment, the length of the carbon nanotubes is less than about 10 μm. In an alternative embodiment, the length of the carbon nanotubes is about 9 μm, or alternatively, about 8 μm, or alternatively, about 7 μm, or alternatively, about 6 μm, or alternatively, about 5 μm, or alternatively, about 4 μm, or alternatively, about 3 μm, or alternatively, greater than about 2 micrometers.

When the nanorod is a carbon nanotube, one can control the diameter of the carbon nanotubes by using substantially uniformly sized catalyst particles. Suitable catalysts for fabricating substantially uniform sized catalyst particles include, but are not limited to copolymer micelles having a transition metal particle incorporated therein, such as iron, cobalt, and molybdenum in the presence of nickel. In addition, the nanotube growth sites can be controlled by careful deposition of the catalyst particles at predefined locations by use, for example, of a block copolymer template that serves to isolate and spatially separate the metal catalyst particles. The deposition of the catalyst-particles can be accomplished via methods known in the art such as spin coating a solution of the catalyst-particles in a matrix as described in Dai et al., U.S. Pat. No. 6,401,526. In certain embodiments, the matrix is a polymer, such as PS-b-P2VP. In one embodiment, the catalyst is a transition metal-containing catalyst such as iron, molybdenum, nickel, cobalt, gold, or a mixture thereof. In a particular embodiment, the transition metal-containing catalyst is a carbon nanotube growth promoting catalyst such as iron, cobalt, and molybdenum in the presence of nickel.

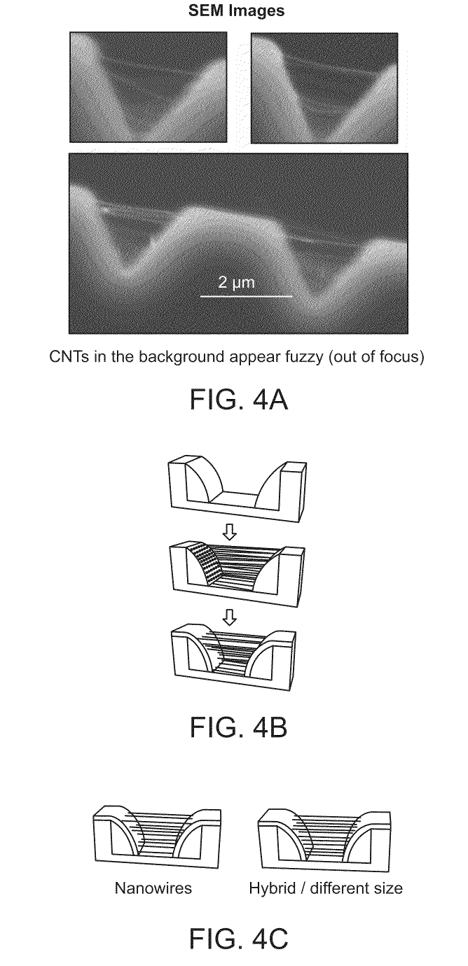

As depicted in FIG. 4C, in some cases, it may be desirable to have an optoelectronic device comprising nanorods of various compositions and/or size. In one embodiment, the array of nanorods comprises nanotubes having different compositions. For example, one layer of nanorods may comprise zinc oxide and another layer may comprise carbon. The composition of the nanorods can be controlled using methods well known to those of skill in the art, including catalyst composition, feed gas, and the like, as described in Islam et al. U.S. Pat. Nos. 7,307,271; 7,208,094; 7,344,961; 7,105,428; 7,087,920; or 6,962,823.

By tailoring the block lengths of block copolymer templates and metal loading, the catalyst size can be controlled which in turn, controls the diameter of the nanorods. The catalyst-containing block copolymers can be produced from either direct polymerization of catalyst-containing monomers or selectively attaching catalyst particle onto one a pre-existing block copolymer template. It has been demonstrated that highly ordered and uniform catalyst particles can be successfully synthesized using this technique. In some embodiments, depending on the composition of the nanorods, the diameter of the nanorods is from about 0.5 nm to about 100 nm. In one embodiment, the diameter of the nanorods is less than about 100 nm, or alternatively, less than about 50 nm, or alternatively, less than about 25 nm, or alternatively, less than about 10 nm, or alternatively, less than about 2 nm. For example, some zinc oxide nanowires have a diameter of about 100 nm. In one embodiment wherein the nanorods are carbon nanotubes, the carbon nanotubes have an average diameter of less than about 1.6 nm. The 1.6 nm diameter is an upper limit and insures single-walled nanotube formation. In an alternative embodiment, the carbon nanotubes have an average diameter of about 1.4 nm, or alternatively, about 1.2 nm, or alternatively, about 1.0 nm, or alternatively, about 0.8 nm, or alternatively, greater than about 0.7 nm. In one embodiment, the carbon nanotubes have an average diameter of about 0.7 nm to about 1.6 nm. This range corresponds to optical bandgaps of 0.65 eV and 1.5 eV (Li, et al. Nano Letters, 2004, 4(2), 317-321).

A vertically graded bandgap design can be fabricated using the above-described device architecture by controlling nanorod diameter from top to bottom. Thus, In one embodiment, the array of nanorods comprises nanorods having different bandgaps. In a particular embodiment, the nanorods in the array have vertically graded diameters, such that the average diameter of the nanorods at the top of the array is smaller than the average diameter of the nanorods at the bottom of the array. It is contemplated that this configuration will offer unprecedented absorption cross-section of solar radiation. The variation of tunable bandgap that can be achieved by quantum wells is limited due to strain caused by lattice mismatch. This design circumvents certain restrictions and enables the CNT-based photovoltaic devices of the invention to achieve higher solar radiation conversion.

When the nanorods are grown in situ, the concentration of suspended nanorods is dictated by the concentration of catalyst-particles on the support structure. The concentration of catalyst particles can be varied to achieve the desired concentration of suspended nanorods. In a particular embodiment, for the nanorods grown in situ, the concentration of catalyst-particles is greater than about 100 catalyst-particles per square micrometer. In an alternative embodiment, the concentration of catalyst-particles is less than about 100 catalyst-particles per square micrometer, or alternatively, less than about 90, or alternatively, less than about 80, or alternatively, less than about 60, or alternatively, less than about 50, or alternatively, less than about 40, or alternatively, less than about 25. However, the yield of suspended nanorods can vary, resulting in a concentration range of the suspended nanorods. In one embodiment, the array of nanorods has a vertically graded density, such that the density of nanorods at the top of the array is lower than the density of nanorods at the bottom of the array.

In a particular embodiment, the nanorods that bridge an indentation of the solid support system are at a concentration of about 10 to about 100 per square micrometer. In an alternative embodiment, the suspended nanorods bridge an indentation of the optoelectronic device substrate are at a concentration of about 10 to about 25 per square micrometer, or alternatively, about 25 to about 50, or alternatively, about 50 to about 75, or alternatively, about 75 to about 100, or alternatively, about 10 to about 50, or alternatively, about 10 to about 75, or alternatively, about 25 to about 75, or alternatively, about 25 to about 100, or alternatively, about 75 to about 100.

Once the nanorods are deposited, a metal layer or electrode can be deposited on opposing walls of the indentation. The electrodes can be any metal or metal alloy capable of conducting a current. The electrodes can be formed by using standard micro fabrication processing. Specific metals which can be used as the electrodes with the optoelectronic device substrate are gold, palladium, platinum, molybdenum, titanium, copper, silver, lead, zinc, aluminum a gold alloy, a palladium alloy, or a platinum alloy, for example.

In some embodiments, the optoelectronic devices disclosed herein further comprise a transparent polymer matrix surrounding the nanorods and contained within the gap. After the nanorods are deposited, as depicted in FIGS. 2 and 5, the nanorods are surrounded by a dielectric material to immobilize the nanorods. Once the nanorods are immobilized, etching exposes the ends of the nanorods to allow for a high-quality junction with the electrodes which are deposited thereafter. In one embodiment, the nanorods are grown in situ, as shown in FIG. 5. In another embodiment, the nanorods are generated, suspended in a dielectric material and deposited onto a substrate to provide the array of nanorods. Etching and deposition of the electrodes completes the optoelectronic device. These embodiments are exemplified in FIGS. 2 and 3. In a further embodiment, the nanorods can first be aligned before they are immobilized. This embodiment is exemplified in FIG. 3. For example, a surfactant can be used to suspend the nanorods, and using a electrical source, the nanorods will align. Then the nanorods can be immobilized using a dielectric material, such as a transparent polymer matrix. In some embodiments, surfactants are associated with the outer surfaces of the nanorods and a transparent polymer matrix surrounding the nanorods.

In some embodiments, the dielectric material comprises porcelain, ceramic, mica, glass, plastic, a polymer, a surfactant, a metal oxide, dry air, distilled water, or a vacuum. In certain embodiments, the dielectric material is a surfactant or polymer, whereas in other embodiments, it may be preferable that the dielectric material be a metal oxide.

### Methods of Preparing the Optoelectronic Devices

Also provided herein is a method for making an optoelectronic device, comprising, or alternatively consisting essentially of or yet further consisting of, the steps of depositing an array of semiconducting nanorods such that the three-dimensional array of semiconducting nanorods spanning the gap; and depositing the first and second electrodes such that at least one nanorod is in contact with the first electrode and the second electrode. In one aspect, the array of nanorods are of a material such that they function as a semiconducting material. In one embodiment, the nanorods are semiconducting nanorods.

Also disclosed herein is a method for making an optoelectronic device, comprising, or alternatively consisting essentially of, or yet further consisting of, the steps of depositing a first electrode stack and a second electrode stack on a solid base and etching a gap defined between the first electrode stack and the second electrode stack; and then depositing an array of nanorods such that the array of semiconducting nanorods are located in, and spanning the gap wherein at least one nanorod is in contact with the first electrode stack and the second electrode stack.

In one embodiment, the methods disclosed herein further comprise, or alternatively consist essentially of, or yet further consist of, the steps of forming an isolated metal contact 14 (see FIGS. 1B, and FIGS. 6B and 6C). The isolated metal contact 14 increases the surface area of the first and second electrodes 13 in the stacked configuration to allow for efficient energy transfer. In some embodiments, the isolated metal contact comprises any one of gold, palladium, platinum, molybdenum, titanium, copper, silver, lead, zinc, zirconium, niobium, tantalum, or aluminum.

Referring to FIGS. 1 and 6, in one embodiment, the depositing the first electrode stack and the second electrode stack comprises, or alternatively consisting essentially of, or yet further consisting of the steps of, successively depositing (a) an effective amount of an insulating material layer 11 to a depth of about 5 nm to about 0.2 μm; (b) depositing an effective amount of a catalyst particle-containing matrix layer 12 over-top the insulating layer 11 to a depth of about 20 nm to about 40 nm; and then (c) depositing an effective amount a metal layer 13 over-top the catalyst particle-containing matrix layer 12 to a depth of about 50 nm to about 0.1 μm; and then (d) depositing an effective amount of an insulating layer 11 over-top the metal layer 13 to a depth of about 5 nm to about 0.2 μm.

In a certain embodiment, multiple layers are desired to form the three-dimensional array of isolated nanorods. Therefore, in some embodiments, steps (a), (b) and (c) are repeated at least two times prior to step (d). The resulting optoelectronic device fabricated by this method is shown in FIGS. 1A, 1B and 6.

Once the desired number of layers are deposited on the solid base, an isolated metal contact is formed at each metal layer. Suitable metals for the metal contact is gold or a gold alloy. This optoelectronic device substrate offers unprecedented control in nanorod spatial arrangement that is unattainable otherwise. The layers are deposited in an amount, or thickness, effective to allow the generation of a bias across the nanorods. For the purpose of illustration only, such amounts include, but are not limited to thickness of about 5 nm to about 0.2 μm. Further, the layers are deposited in amounts effective to generate isolated nanorods. The removal of the polymeric template (which can be accomplished by thermal methods, for example) exposes the nanoparticle catalysts for the growth of the nanorods.

In one embodiment, the optoelectronic device has a solid base 10 which has an indentation (see FIGS. 4A, 4B and 5, for example). The indentation can be used to contain the nanorods 15. In some embodiments, the nanorods are grown in situ in the indentation such that the nanorods bridge the indentation. In such embodiments, the optoelectronic device can be produced by providing a solid base having an indentation, disposing the array of semiconducting nanorods such that the array of semiconducting nanorods are at least partially contained within the indentation, and depositing the first and second electrodes. The solid base having an indentation can be provided by methods which are well known to those of skill in the art, such as by the use of a mold or etching. In some embodiments, the solid base is a silicon wafer. In some embodiments, an oxide layer is deposited on the solid base having an indentation. Referring to FIG. 4B, in some embodiments, the optoelectronic device can be produced by providing a solid base and first forming walls in the solid base by resist patterning followed by etching. The oxide layer can then be deposited and the indentation or gap formed by an oxide layer and the indentation provided via etching methods well known to one of skill in the art.

It is contemplated that the array of nanorods can be disposed using any method known to those of skill in the art. In some embodiments, the array of nanorods is deposited by surrounding the nanorods with a transparent polymer matrix or suspending nanorods in a surfactant (FIGS. 2, 3 and 5). In some embodiments, disposing the array of semiconducting nanorods comprises depositing a catalyst particle-containing matrix layer and growing the array of semiconducting nanorods in situ. Atomic force microscopy can be used to estimate nanocatalyst size and reveal the degree of ordering (Amer, et al. U.S. Pat. No. 5,144,833). X-ray photoelectron spectroscopy can provide information related to stoichiometry of bimetallic nanocatalysts (Larson et al. U.S. Pat. No. 5,315,113).

The in situ growth of semiconducting nanorods can be accomplished using methods well known to those of skill in the art. For example, arc discharge(Iijima et al. Nature, 1991, 354, 56-58 and Ebbesen et al. Nature 1992, 358, 220-222), laser ablation (Anazawa et al. U.S. Pat. No. 7,132,039, Guo et al. Chemical Physics Letters, 1995, 243, 49-54, A. Thess et al. Science 1996, 273, 483-487) and chemical vapor deposition (Lee, et al. U.S. Pat. No. 6,350,488). In some embodiments, the depositing an array of semiconducting nanorods comprises carbon vapor deposition. In some embodiments, the nanorods are carbon nanotubes. The carbon nanotubes can be grown via chemical vapor deposition (CVD) such that the carbon nanotubes span across the preformed trenches of the support structure and are thus suspended in air (FIGS. 1, 4A, 4B, 4C, 6, 9, 10 and 11). One would expect the synthesis of carbon nanotubes to produce a mixture of both metallic and semi-conducting CNTs. Since only semi-conducting tubes are desired, removal of the metallic tubes can be accomplished by electrical and chemical means. For example, using the selective chemical interaction of CNTs with diazonium reagent, the metallic tubes are completely screened (Li, et al. Journal of Physical Chemistry B, 2001, 105, 11424-11431).

In some embodiments, the junction between array of semiconducting nanorods and the first and second electrodes is formed by applying a pattern and etching the array of semiconducting nanorods prior to depositing the first and second electrodes.

The electrodes can be deposited using angular deposition and it is contemplated that the first and second electrodes can be any conductive material. In some embodiments, the first and second electrode are each independently gold, palladium, platinum, molybdenum, titanium, copper, silver, lead, zinc or aluminum. In addition, one method that can be used to create a bias across the array of semiconducting nanorods is by using a different metal for the first and second electrodes. In some embodiments, the first and second electrodes are different.

The series of self-assembled block copolymer templates methods disclosed herein uses rationally synthesized nanocatalysts with controlled properties and consequently produce high quality, low defect CNTs with predetermined diameter and density. The novel optoelectric device substrates disclosed herein enable control of CNT spatial arrangement in 1D—isolated individual CNTs; 2D—CNTs in pseudo-parallel arrangement; and 3D—a large number of electrically isolated CNTs. Layer-by-layer control of CNT diameter can be also achieved by using catalysts of various sizes. This flexible architecture also facilitates tube manipulations, such as electrical burning and chemically removing or suppressing metallic tubes.

As disclosed herein, a vertically graded bandgap design can be fabricated by controlling CNT diameter from top to bottom. It is contemplated that this configuration will result in unprecedented absorption cross-section of solar radiation. CNTs as photoabsorbing materials offer unique advantages over quantum dots since the CNT surface is seamlessly perfect with no dangling bonds present. The variation of tunable bandgap that can be achieved by quantum wells is limited due to stain generated from lattice mismatch. The disclosed design disclosed herein circumvents all of the aforementioned restrictions.

### Uses for the Optoelectronic Devices

The device architecture contains high quality, suspended, electrically isolated and low defect nanorods. The greatly enhanced optical absorption enabled by this novel architecture, isn't possible if nanorods are in the form of bundles. The inauguration of this research opens the door for realization of a multitude of applications, for example, using nanorods as photoabsorbers: broadband photodetectors and photovoltaic devices. Non-radiative recombinations from (a) the interaction of nanorods with their underlying substrate, (b) defects in nanorods, (c) tunneling at intertube junctions and (d) charge transfer between nanorods in bundles are thus eliminated. In some embodiments, the electrodes are connected to an external power source.

As disclosed herein, the optoelectronic devices can be used as a method for producing an electrical current. Therefore, the optoelectronic devices can be used as an energy source by exposing the devices to the appropriate activating energy. In certain embodiments, the device disclosed herein can be used as a photovoltaic cell, photodetector or solar cell. In addition, a plurality of the photovoltaic cells can be used to generate a photovoltaic array. Such devices will produce a voltage and supply an electric current when illuminated. Further uses include incorporation in photomultiplier tubes. Such photomultiplier tubes generally containing a photocathode which emits electrons when illuminated, the electrons are then amplified by a chain of dynodes. Alternatively, the device disclosed herein can be incorporated in a phototube which emits electrons when illuminated and in general behaves as a photoresistor.

Extremely bright tunable IR emitters can be fabricated based on this platform. Furthermore, this flexible architecture also facilitates tube manipulations, such as electrical burning and chemically removing or suppressing metallic tubes. This versatile design can also be used for fluorescence-based chemical detection. The layers are independently addressable and potentially individual tubes can be addressed separately.

These and other embodiments of the technology will readily occur to those of ordinary skill in the art in view of the disclosure herein and are specifically contemplated.

### EXAMPLES

The present technology is further understood by reference to the following examples. The present technology is not limited in scope by the examples, which are intended as illustrations of aspects of the present technology. Any methods that are functionally equivalent are within the scope of the present technology. Various modifications of the present technology in addition to those described herein will become apparent to those skilled in the art from the foregoing description and accompanying figures. Such modifications fall within the scope of the appended claims.

### Example 1

### General Carbon Nanotubes Synthesis

In general, as-synthesized semiconducting SWCNTs yield a mixture of semiconducting and metallic SWCNTs. Metallic tubes will not contribute to photoluminescence and photovoltage or photocurrent but rather quench photocurrent produced by optically active excitons and wash out photoluminescence if they are in contact with semiconducting SWCNTs. In addition, defects create potential barriers for charge transfer and are non-radiative recombination sites. Therefore the investigation of fundamental properties and realization of CNT-based optoelectronic devices hinge upon the ability of synthesizing SWCNTs, which are not only homogenous and substantially defect-free but also comprise pure semiconducting tubes.

i. Nanocatalysts Derived from Block Copolymer Templates

A block polymer consists of two or more chemically immiscible homopolymers joined together by covalent bonds. The intrinsic immiscibility of each block coupled by covalent linkages coerces these macromolecules to self-assemble according to the fundamental law of physics into a myriad of well-ordered morphologies with domain size ranging from a few to tens of nanometers (Park, et al. Science, 1997, 276, 1401-1404, Lopes, et al. Nature, 2001, 414, 735-738, Thurn-Alberchet, et al. Science, 2000, 290, 2126-2129, Hawker, et al. Material Research Bulletin, 2005, 30(12), 952-966, Föster, et al. Journal of Chemical Physics, 1996, 104(24), 9956-9970). Discrete and periodically ordered nanodomains can be utilized for synthesizing nanocatalysts. This approach allows for the unprecedented potential of controlling size, spacing and composition of nanocatalysts (Lu, et al. Journal of Physical Chemistry B, 2006, 110(13), 6655-6660, Lu, et al. Langmuir, 2006, 22, 5174-5179, Fu, et al. Journal of Physical Chemistry B, 2004, 108(20), 6124-6129, Lu, et al. Journal of Physical Chemistry B, 2006, 110(13), 10585-10589, Lu, et al. Nanotechnology, Santa Clara USA, 2007, Bhaviripudi, et al. Nanotechnology, 2006, 17(20), 5080-5086, Bennett, et al. Advanced Materials, 2006, 18(17), 2274-2279, Lastella, et al. Journal of Materials Chemistry, 2004, 14(12), 1791-1794, Lu, et al. Chemistry of Materials, 2005, 17, 2227-2231).

The catalyst-containing block copolymers can be produced from either direct polymerization of catalyst-containing monomers or selectively attaching catalyst species onto one of the pre-existing blocks. It has been demonstrated that highly ordered and uniform nanocatalysts can be successfully synthesized using either thin film self-assembled or solution self-assembled morphologies. Polystyrene-b-poly(methylethylferrocenylsilane) has been self-organized on a thermally grown silicon oxide surface with iron-containing cylinders arranged in a hexagonally closely-packed lattice. After removal of polymeric material, discreet iron-containing nanostructures have been formed. The TEM image is inserted for a clearer view. A monolayer of self-assembled micelles of iron complexed polystyrene-b-poly(2-vinylpyridine) with the core composed of iron-complexed poly(2-vinylpyridine) and the shell formed by polystyrene has been deposited onto a properly treated thermally grown silicon oxide surface. Periodically ordered iron nanoparticles have been created.

ii. Synthesis of Nanocatalysts with Adjustable Properties for Controllable CNT Growth

The size and spacing of nanocatalysts can be controlled by tailoring the block lengths. Consequently, the diameter and density of CNTs can be adjusted accordingly. Smaller and denser cobalt nanocatalysts produced from cobalt complexed PS₄₇₅-b-P2VP₁₄₁ yield a denser CNT network. Smaller nanocatalysts yield smaller CNTs. Single and bimetallic nanocatalysts are obtained, suggesting that the composition of nanocatalysts can be rationally tuned by adjusting the stoichiometry of metal precursors. Therefore high catalytically active bimetallic nanocatalysts which can preferentially grow semiconducting CNTs with narrow chiral distribution can be synthesized using nanocatalysts prepared from this block copolymer template approach.

The block copolymer approach is fully compatible with conventional photoresist processing. Ordered arrays of nanocatalysts have been generated at locations determined by top-down lithography. Spatially selective growth of high quality suspended CNTs across trenches over a large surface area has been achieved. Si nanowires are successfully grown at lithographically defined locations on a 3 inch wafer, using patterned gold nanoparticle arrays created by a combination of top-down lithography with bottom-up self-assembly of a block copolymer. A state-of-the-art chemical vapor deposition system with the ability to grow CNTs on a 4 inch wafer can be used to apply these methods.

### Example 2

### Fabrication of High Quality, Low Defect, Electrically Isolated SWCNTs

Spatially defined arrays of nanocatalysts can be created by combining top-down lithography with bottom-up self-assembly. High quality, low defect, electrically isolated and suspended SWCNTs can be fabricated on a device format as disclosed herein. First, deposit a sacrificial oxide layer, such as Al₂O₃, MgO or SiO₂, on top of each nanocatalyst monolayer so that nanocatalysts are sandwiched in between the sacrificial layer and the thin metal contact layer, such as Pt, for example. After repeating this film stack several times, a metal contact can be formed by using standard microfabrication processing. Deep trenches can be created by anisotropic etch and followed by an isotropic etch to partially remove sacrificial layers for uncovering nanocatalysts. Chemical vapor deposition can then be carried out to grow suspended SWCNTs.

The platform disclosed herein offers exceptional controls that are unattainable otherwise. This method provides layer-to-layer control of catalyst properties including size, spacing and composition by adjusting self-assembled block copolymer properties. Thus SWCNT properties can be tailored layer by layer independently (Lu, et al. Langmuir, 2006, 22, 5174-5179; Cheng, et al. Applied Physics Letters, 1998, 72, 3282-3284; Kitiyanan, et al. Chemical Physics Letters, 2000, 317, 497-503; Maruyama, et al. Chemical Physics Letters, 2002, 360, 229-234; Takagi, et al. Nano letters, 2006, 6(12), 2642-2645; Maruyama, et al. Chemical Physics Letters, 2003, 375, 553-559; Su, et al. Chemical Physics Letters, 2000, 322(5), 321-326; Zhao, et al. Nanotechnology, 2005, 16, 575-581; Cheung, et al. Journal of Physical Chemistry B, 2002, 106, 2429-2433; Li, et al. Journal of Physical Chemistry B, 2001, 105, 11424-11431; Lolli, et al. Journal of Physical Chemistry B, 2006, 110(5), 2108-2115; Miyauchi, et al. Chemical Physics Letters, 2003, 377(1-2), 49-54; Jorio, et al. Physical Review B, 2005, 72, 075207; Bachilo, et al. Journal of the American Chemical Society, 2003, 125(37), 11186). CNT density within a layer can be tailored by the catalyst spacing, dictated by block lengths of the block copolymer template, and the nanocatalyst array size, mainly controlled by the isotropic etch step. Layer-to-layer spacing can be adjusted by controlling the sacrificial layer thickness. Thus, isolated SWCNTs arranged in 1D, 2D and 3D can be created. The above outlined process is fully compatible with conventional semiconducting device fabrication. This proposed work can be carried out on a 4 inch wafer format and allows the evaluation of a number of geometric designs in close proximity for achieving isolated high-density defect-free semiconducting SWCNTs.

### Example 3

High-Quality, Low-Defect Semiconducting Nanotubes with a Controlled Diameter via Co/Mo Nanocatalysts with a Tunable Diameter

The disclosed invention starts with the synthesis of nanocatalysts with the desired properties for promoting the selective growth of high-quality semiconducting SWCNTs with controlled diameter.

i. Catalyst Composition

Bimetallic nanocatalysts such as Co—Mo produce high-yield and low-defect SWCNTs with fewer chiral selections (Jorio, et al. Physical Review B, 2005, 72, 075207, Bachilo, et al. Journal of the American Chemical Society, 2003, 125(37), 11186, Miyauchi, et al. Chemical Physics Letters, 2003, 377, 49-54). The ratio of semiconducting-to-metallic tubes is 11:1 (Itkis, et al., supra). It has been suggested that the presence of Mo may (a) promote the nucleation of SWCNTs (Bachilo, et al. Journal of the American Chemical Society, 2003, 125(37), 11186, Dai, Accounts of Chemical Research, 2002, 35, 1035-1044, Deng, et al. Nano Letters, 2004, 4(12), 2331-2335) and/or (b) act as a matrix to stabilize the catalytically active cobalt nanoclusters against aggregation at high growth temperatures (Herrera, et al. Journal of Catalysis, 2004, 221(2), 354-364). Thus Co—Mo nanocatalyst alloys are to be used for the disclosed system to preferentially grow high quality SWCNTs.

Two amphiphilic block copolymers, polystyrene-b-poly(2-vinylpyridine), PS-b-P2VP, and polystyrene-b-polybutadiene-b-poly(2-vinyl pyridine), PS-b-PB-b-P2VP, can be used for synthesizing Co—Mo nanocatalysts. These two block polymers can be self-assembled in solution and/or on a solid (Lu, et al. Journal of Physical Chemistry B, 2006, 110(13), 6655-6660, Segalman, Macromolecules, 2003, 36(9), 3272-3288, Huckstadt, et al. Macromolecular Chemistry and Physics, 2000, 201(3), 296-307). In addition, they consist of polymer segment(s) that can interact with metal species, therefore localizing them.

PS-b-P2VP, can complex with group VIIIA transition metals (Kurihara, A Journal of Chemical Sciences, 2000, 55, 277-284), but Mo(VI) can't be effectively attached onto the pyridine units. Equimolar Fe and Mo yields nanoparticles consisting of only 15 mol % of Mo based on XPS analysis (Lu, et al. Journal of Physical Chemistry B, 2006, 110(13), 6655-6660). Protonating the unreacted pyridine groups would produce pyridinium cations which can then react with Mo-based anions to form ionic bonds (Martin, et al. Macromolecules, 1996, 29(18), 6071-6073). Therefore Mo-based bimetallic nanoparticles are expected to be formed. PS-b-PB-bP2VP should be able to self-organize and incorporate metals with different chemical affinities. Mo(VI) is expected to attach onto the PB chains since alkene groups can react with Mo species to form π-complexes (Shi, et al. Journal of Organometallic Chemistry, 1988, 348(3), 357-360, Pearson et al. Journal of the Chemical Society, Chemical Communication, 1989, 389-391, Loginova, et al. Chemistry of Materials, 2004, 16(12), 2369-2378), while VIIIA metals can be captured by P2VP. After depositing a monolayer of solution micelles onto a surface, UV-Ozonation can be used to remove the polymer template, creating highly ordered nanocatalysts.

ii. Catalyst Size

The density function theory calculation has indicated that the formation energies for semiconductor SWCNTs are lower than those of metallic SWCNTs. Furthermore, the energy difference in formation increases as diameter decreases (Li, et al. Journal of Physical Chemistry B, 2005, 109(15), 6968-6971). This result is supported by experimental findings: small-diametered SWCNTs grown under a mild growth condition have a higher percentage of semiconducting SWCNTs (Miyauchi, et al. Chemical Physics Letters, 2003, 377(1-2), 49-54, Li, et al. Journal of Physical Chemistry B, supra, Li, et al. Nano Letters, 2004, 4(2), 317-321). Because the block copolymer approach can controllably synthesize uniform and small-diametered nanocatalysts, that aren't addressable by top-down lithography, selective growth of semiconducting SWCNTs should be enhanced. Tailoring block lengths of block copolymer templates and metal loading, the size of nanocatalysts can be adjusted to synthesize high-quality, low-defect semiconducting SWCNTs with tunable diameter. The upper limit of catalysts size will be set for generating 1.6 nm tubes to insure SWCNT formation. The lower limit of catalysts size will be set for producing 0.7 nm tubes. This range corresponds to optical bandgaps of 0.65 eV and 1.5 eV (Weisman, et al. Nano Letters, 2003, 3, 1235-1238).

Atomic force microscopy can be used to estimate the size of nanocatalysts and reveal the degree of ordering. X-ray photoelectron spectroscopy (XPS) can be used to provide information related to stoichiometry of bimetallic nanocatalysts.

### Example 4

Iron Nanoparticles Derived from Block Copolymer Templates

The production of uniform sized catalyst nanoparticles with identical catalytic activity serves to achieve CNTs with homogenous properties and to produce high yield CNTs with minimum amorphous carbon. Pyridine-based block copolymers, polystyrene-b-poly(2-vinyl pyridine) (PS-b-P2VP) and polystyrene-b-poly(4-vinyl pyridine) (PS-b-P4VP), purchased from Polymer Source, were used as templates for the preparation of iron nanoparticles. Iron(II) chloride tetrahydrate from Aldrich was used as the iron precursor. Toluene from Aldrich was used as a solvent.

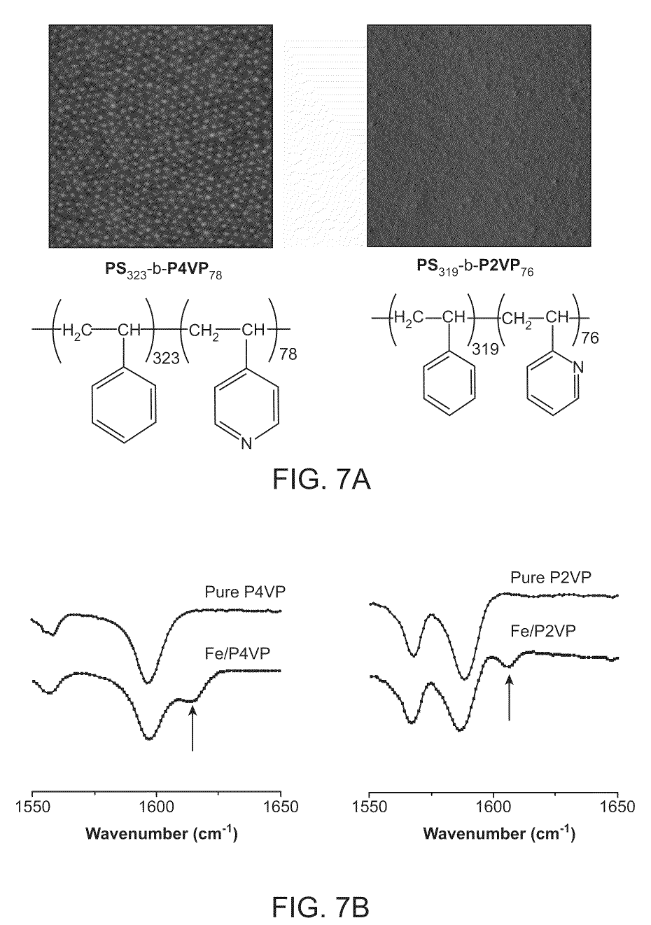

In this set of experiments, PS₃₂₃-b-P4VP₇₈ and PS₃₁₉-b-P2VP₇₆ were first dissolved in toluene. The iron(II) chloride was introduced to yield a 0.25 wt % solution with iron/pyridyl molar ratio of 0.13. After stirring for 24 h at room temperature, the metal precursor-loaded polymer solutions were spin-coated on patterned silicon dioxide surfaces. Oxygen plasma was then used to remove the block copolymer templates. FIG. 7a shows AFM height images of the surface morphology after treatment with oxygen plasma. AFM height analysis was performed on a Veeco Dimension 5000. Iron nanoparticles with an average height of 1.6 nm, according to AFM height analysis, were derived from using PS₃₂₃-b-P4VP₇₈ as template. In this experiment, the PS₃₁₉-b-P2VP₇₆ template did not generate nanoparticles.

To determine the ability of iron(II) to complex with pyridine groups, regardless to the location of nitrogen on the pyridine ring, poly(2-vinylpyridine) (P2VP) and poly(4-vinylpyridine) (P4VP) (purchased from Polymer Source) were used to study metal complexation. FTIR spectra, displayed in FIG. 7b, before and after inclusion of iron(II) chloride tetrahydrate, were acquired using a Nicolet MagNA-IR 850. The appearance of new bands at 1616 cm⁻¹ and 1603 cm⁻¹ in iron-loaded P4VP and P2VP, respectively, are characteristic of pyridine complexes with metals (Liu, et al. Reactive and Functional Polymers 2000, 44, 55-64; Bekturov, et al. Polymer Journal 1991, 23(4), 339-342). As validated by FTIR analysis, pyridine with its lone pair of electrons on nitrogen can complex with iron (II), a transition metal species with unfilled d-orbitals, as indicated in FIG. 7b.

Due to partial screening of nitrogen in P2VP, PS₃₁₉-b-P2VP₇₆, molecules cannot themselves self-assemble in toluene. However, a sufficient amount of metal complexed with 2-vinyl pyridine units render the P2VP block more hydrophilic and thus induces micellization in toluene. To synthesize CNTs with a diameter of about 1 nm, the iron oxide nanoparticles should have a height of less than about 2.0 nm. In general, the nanoparticles should have a height of about 2 nm to about 5 nm. Consequently the molar ratio of iron(II) to pyridine was adjusted to be around 0.13. Statistically, only every 7^{th} 2-vinyl pyridine functional group has iron attached. The absence of nanoparticles on a surface prepared using the iron loaded PS₃₁₉-b-P2VP₇₆ solution indicated that P2VP with low iron(II) content is not hydrophilic enough to induce micellization in toluene.

On the contrary, P4VP chain is so polar that reverse micelles of pure PS₃₂₃-b-P4VP₇₈ block polymers can be formed in toluene. Despite the tendency of forming intra- and intermolecular bonds between metals and 4-vinyl pyridine and the multi-valency nature of a polymer system, iron nanoparticles with uniform size have been prepared using the PS₃₂₃-b-P4VP₇₈ template. It is contemplated that this is due to a relatively low stability constant value of the complex formed by iron (II) and 4VP, compared to Co(II) and Ni(II) (Kurihara, M. A Journal of Chemical Sciences 2000, 55, 277-284; Stability constants of metal-ion complexes [2d ed.: supplement, no. 2] Imprint: Oxford; New York Pergamon Press, c1979-1982).

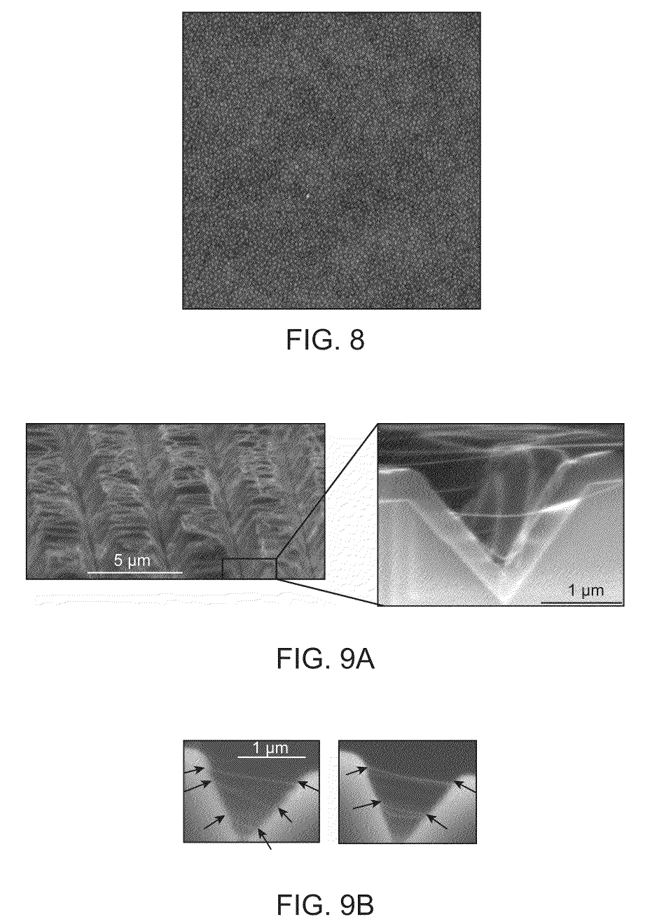

Due to the excellent film forming capability of a polymeric material, solution micelles can be distributed evenly on a surface. FIG. 8 is an AFM height image demonstrating that uniform sized iron oxide nanoparticles can be evenly distributed over a 3 μm square surface area. It is known that high molecular weight polymers have a tendency to form conforming films over topographic surfaces. Therefore, it is conceivably a monolayer of PS₃₂₃-b-P4VP₇₈ micelles with iron sequestered in the core. These can also be deposited on the sloped sidewalls of trenches.

### Example 5

### Growth Conditions for Selectively Growing High-Quality Semiconducting SWCNTs

SWCNTs can be grown selectively on smaller nanocatalysts at low carbon concentration, implying that carbon solubility varies with nanocatalyst size. In addition, large amounts of amorphous carbon is observed on surfaces when very small nanocatalysts are used, indicating that smaller nanocatalysts are more catalytically active (Lu, et al. Langmuir, 2006, 22, 5174-5179, Bhaviripudi, et al. Nanotechnology, 2006, 17(20), 5080-5086). Thus, carbon stock concentration and feed rate need to be adjusted to minimize amorphous carbon deposition and improve growth yield. Using a state-of-the-art CVD chamber can enable SWCNT synthesis and device fabrication on a 4 inch format and offer precise control of gas composition and flow. By adjusting the growth parameters, high-yield and low-defect semiconducting SWCNTs can be synthesized. Scanning electron microscopy and transmission electron microscopy can be used to characterize growth yield and determine the number of tube walls. The Raman spectroscopic technique can be used to probe tube quality, diameter and chirality, a compliment to the photoluminescence measurement which is discussed in detail in the following example. All of these characterizations can identify growth parameters for achieving defect-free tubes.

Simulations indicate that melting temperature and on-set of graphitization temperature reduce substantially with shrinking nanocatalyst size (Jiang, et al. Physical Review B, 2007, 75(20), 205426, Ding, et al. Journal of American Vacuum Science and Technology A, 2004, 22, 1471-1476, Ding, et al. Applied Physics letters, 2006, 88(13) 133110). Moreover, the eutectic point for carbon-metal occurs at lower carbon concentration. It is also predicted by simulation that nanocatalyst alloys can further reduce the eutectic point. Thus, smaller-diametered nanocatalyst alloys created by block copolymer templates can enable a mild growth condition which is favorable for growing semiconducting SWCNTs (Li, et al. Journal of Physical Chemistry B, 2005, 109(15), 6968-6971). Furthermore, lowering the growth temperature can make CNT synthesis more compatible with conventional device fabrication.

### Example 6

### CNT Synthesis and Characterization

Sloped sidewalls were formed by using a one-step patterning processing. (100) Si wafers with 100 nm of thermal silicon oxide with AZ 1512 resist were exposed on a Karl-Suss MA-6 mask aligner. Wafers were then developed with an 0.26N TMAH developer. Wet etching of the SiO₂ was performed using a hot KOH bath to form sloped trenches. After resist stripping with acetone, buffered HF was employed to remove the 100 nm thermal SiO₂, a layer of 50 nm silicon oxide was then deposited by PECVD. Finally, iron(II) loaded PS₃₂₃-b-P4VP78 micelles were deposited. After stripping the block copolymer template by UV ozonation, catalyst nanoparticles were formed on the sidewalls of the trenches. The substrate was then treated with oxygen plasma for 15 min followed by CVD growth of SWNTs at 900° C. A flow of gas composed of 1500 sccm CH₄ and 1000 sccm H₂ and 20 sccm C₂H₄ was introduced and maintained for 5 min. After 5 min. the samples were cooled to room temperature under the protection of H₂ and inspected in a Hitachi S-4500 scanning electron microscope. The CNT properties were studied using Raman spectroscopy.

FIG. 9a is a representative set of tilted SEM images showing SWNTs grown on sloped sidewalls. By creating suspended and isolated CNTs in a 3D configuration, the density of isolated tubes per unit volume has been greatly increased. It has been found that the majority of tubes are aligned orthogonal to the orientation of the trenches, independent of the gas flow direction. This result implies that surface topography can induce CNTs to be aligned. FIG. 9b shows typical SEM images showing CNTs emitting from one sidewall and reaching and anchoring onto the sidewall of the opposite side of the trench. The nanotubes are more or less parallel to each other, suggesting that the growth is pseudo epitaxial. This is the first demonstration of fabricating a 3-dimensional array of suspended, isolated and pristine CNTs.

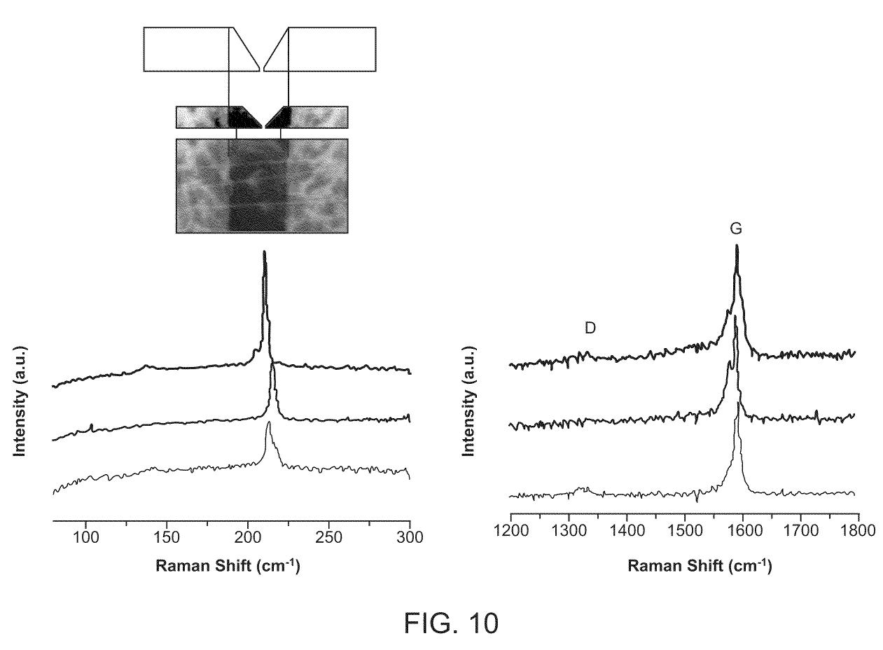

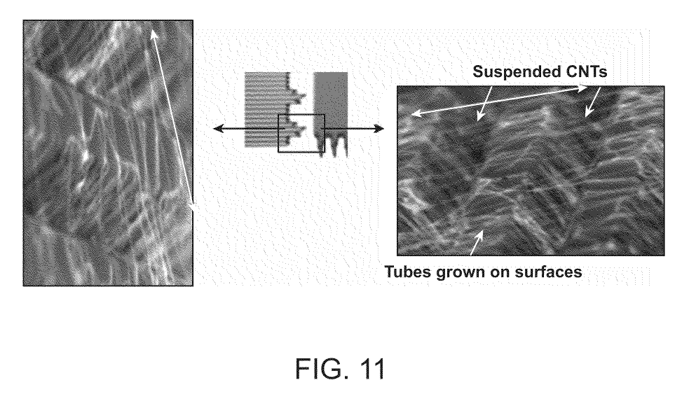

Suspended CNTs with the absence of the substrate interaction yield greatly enhanced Raman signals (Lu, et al. J. Phys. Chem. B 2006; 110(22), 10585-10589) which are used as an accurate determination of the nanotube diameters (excitation wavelength=635.85 nm, laser illumination area=1 μm², integrated time=150 sec, laser power=1.0 mW). SWNTs show characteristic low-energy peaks in their Raman spectra corresponding to the radial breathing vibrational modes with A1g symmetry. Radial breathing vibration is unique to nanotubes with one or few walls. Since the frequency of the radial breathing mode (RBM) is inversely proportional to CNT diameter, the diameters of CNTs can thus be estimated. FIG. 10 is a group of Raman spectra. The RBM bands are between 210 to 230 nm indicating that the majority of tubes are around 1 nm. Without being bound by theory, it is believed that such uniform tube diameters were made possible by forming highly uniform nanocatalysts, which was in turn made possible by the self-assembled polymer micelles. The absence of a D band (which is related to amorphous carbon and defects) indicates that high quality, defect-free SWNTs were synthesized in spatially controlled three-dimensional locations.

When the nanotube orientation is parallel to the polarization of the incident laser light, the intensity of Raman modes is maximum (Park, et al. J. Korean Phys. Soc. 2006, 48(6), 1347-1350; Duesberg, et al. Phys. Rev. Lett. 2000, 85(25), 5436-5438). FIG. 11 shows two Raman spectra for side-by-side comparison of Raman signal intensity of CNTs from two trenches orientated perpendicularly to each other (refer to the inset optical image in FIG. 11). Raman intensities in this figure have been normalized by integrated Raman intensity of a crystalline Si. When a trench is orientated perpendicularly to the laser light, the CNT suspended between the trench shows much stronger Raman signals. However, the Raman signals of a CNT from an adjacent trench, with the trench aligned to the polarization direction of the laser light, are much weaker. This result, confirmed by the SEM inspection, indicates that the suspended CNTs are oriented more or less oriented 90 degrees to the sidewall of a trench. Thus, CNTs have been grown pseudo epitaxial from sidewalls of trenches. This implies that texture on a surface can be used to induce tube alignment.

Although several embodiments of the invention are described herein in detail, it will be understood by those skilled in the art that variations may be made thereto without departing from the spirit of the invention or the scope of the appended claims.

What is claimed is:

1. An optoelectronic device, comprising:
at least one first electrode;
at least one second electrode disposed opposite the at least one first electrode, such that a gap is defined between the at least one first electrode and the at least one second electrode; and
a three-dimensional array of nanorods spanning the gap and wherein at least one nanorod is in contact with the first electrode and the second electrode.

2. The optoelectronic device of claim 1, wherein the nanorods are semiconducting nanorods.

3. An optoelectronic device substrate, comprising:
a first electrode stack comprising a plurality of stacked, spatially-separated first electrodes; and
a second electrode stack comprising a plurality of stacked, spatially-separated second electrodes disposed opposite the plurality of first electrodes, such that a gap is defined between the first electrode stack and the second electrode stack.

4. The optoelectronic device substrate of claim 3, further comprising a catalyst particle-containing matrix layer between neighboring first electrodes in the first electrode stack and a catalyst particle-containing matrix layer between neighboring second electrodes in the second electrode stack.

5. The optoelectronic device substrate of claim 3 or 4, further comprising a layer of insulating material between neighboring first electrodes in the first electrode stack and a layer of dielectric material between neighboring second electrodes in the second electrode stack.

6. The optoelectronic device of claim 1, further comprising a solid base defining an indentation, wherein the at least one first electrode, the at least one second electrode and the three dimensional array of nanorods are at least partially contained within the indentation.

7. The optoelectronic device of claim 6, wherein the indentation has a step-shaped cross-sectional profile.

8. The optoelectronic device of claim 6, wherein the indentation has sloped sidewalls, such that the indentation is wider at its mouth than at its base.

9. An optoelectronic device of claim 6, wherein the solid base comprises an insulating layer or is silicon.

10. The optoelectronic device of claim 1, further comprising a catalyst particle-containing matrix layer between the base and at least one of the first or second electrodes.

11. The optoelectronic device of claim 10, wherein the catalyst is a nanorod forming catalyst or a transition metal-containing catalyst.

12. The optoelectronic device of claim 1, further comprising a transparent polymer matrix surrounding the nanorods.

13. The optoelectronic device of claim 1, further comprising surfactants associated with the outer surfaces of the nanorods and a transparent polymer matrix surrounding the nanorods.

14. The optoelectronic device of claim 1, wherein the nanorods are surrounded by a dielectric material.

15. The optoelectronic device of claim 1, wherein the first and second electrodes are different.

16. A method for making the optoelectronic device of claim 1, comprising
providing a solid base having a gap;
depositing an array of semiconducting nanorods such that the three-dimensional array of nanorods spanning the gap; and
depositing the first and second electrodes such that at least one nanorod is in contact with the first electrode and the second electrode.

17. A method for making the optoelectronic device substrate of claim 3, comprising
providing a solid base
depositing a first electrode stack and a second electrode stack on the solid base;
etching a gap defined between the first electrode stack and the second electrode stack; and
depositing an array of semiconducting nanorods such that the array of semiconducting nanorods are located in, and spanning the gap wherein at least one nanorod is in contact with the first electrode stack and the second electrode stack.

18. The method of claim 16 or 17, wherein the depositing the first electrode stack and the second electrode stack comprises successively depositing:
a) an insulating layer;
b) a catalyst particle-containing matrix layer;
c) a metal layer; and
d) an insulating layer.

19. A method for making the optoelectronic device of claim 6, comprising a solid base having an indentation, disposing the array of semiconducting nanorods such that the array of semiconducting nanorods are at least partially contained within the indentation, and depositing the first and second electrodes.

20. The optoelectronic device of claim 1, wherein the electrodes are connected to an external power source.

21. A method for producing an electrical current, comprising exposing the optoelectronic device of claim 1 to an illumination source.

22. A photodetector, comprising the optoelectronic device of claim 1 as an energy source.

23. A photovoltaic cell, comprising the optoelectronic device of claim 1 as an energy source.
